(19) United States
(12) Patent Application Publication
(10) Pub. No.: US 2002/0182342 A1
(43) Pub. Date: Dec. 5, 2002

(54) Optical quality silica films

(76) Inventors: Luc Ouellet, Granby (CA); Manuel Grondin, Granby (CA); Jonathan Lachance, Granby (CA); Stephane Blain, Sherbrooke (CA)

Correspondence Address: MARKS & CLERK, P.O. BOX 957, STATION B, OTTAWA, ON, K1P 5S7, CA

(21) Appl. No.: 09/833,711

(22) Filed: Apr. 13, 2001

(51) Int. Cl. C23C 16/00; B05D 3/02

(52) U.S. Cl. 427/569; 427/376.2; 427/255.28

(57) ABSTRACT

A method of depositing an optical quality silica film on a substrate is described wherein the film is formed on the substrate by plasma enhanced chemical vapor deposition (PECVD) in the presence of reactive gases while controlling the total pressure of the gases. The as-deposited film is then subjected to a low temperature treatment between 400° to 1200° C. to minimize the presence of contaminant compounds in the film.

### FIELD OF THE INVENTION

The present invention relates to the deposition of films onto a substrate, and in particular to the deposition of optical quality films for use in optical fiber communications, and more particularly to a method of manufacturing high quality silica films for use in waveguides and the like, for example in the manufacture of optical multiplexers and demultiplexers.

### BACKGROUND OF THE INVENTION

In the manufacture of optical devices, a common requirement is the fabrication of high quality silica films. For example, the manufacture of optical Multiplexers (Mux) and Demultiplexers (Dmux) using silica waveguides requires the deposition onto a silicon wafer of extremely transparent optical quality silica films in the 1.30 bi-directional narrow optical band and/or in the 1.55 μm video signal optical band, which the International Telecommunications Union (ITU) recommends for a Wavelength Division Multiplexing (WDM) transport network and for optical access networks for Fiber-To-The-Home (FTTH):

The following articles describe prior art techniques for depositing silica films: Hoffmann M., Low temperature, nitrogen doped waveguides on silicon with small core dimensions fabricated by PECVD/RIE, ECIO'95, 299,1995; Bazylenko M., Pure and fluorine-doped silica films deposited in a hollow cathode reactor for integrated optic applications, J. Vac. Sci. Technol. A 14 (2), 336, 1996; Uchida N., Passively aligned hibrid WDM module integrated with spot-size converter integrated laser diode for fibre-to-the-home, Electronic Letters, 32 (18), 1996; Inoue Y., Silica-based planar lightwave circuits for WDM systems, IEICE Trans. Electron., E80C (5), 1997; Inoue Y., PLC hybrid integrated WDM transceiver module for access networks, NTT Review, 9 (6), 1997; Hoffmann M., Low-loss fiber-matched low-temperature PECVD waveguides with small-core dimensions for optical communication systems, IEEE Photonics Tech. Lett., 9 (9), 1238,1997; Takahashi H., Arrayed-waveguide grating wavelength multiplexers for WDM systems, NTT Review, 10 (1), 1998; and Himeno A., Silica-based planar lightwave circuits, IEEE J. of Selected Topics in Quantum Electronics, 4 (6), 1998.

The as-deposited silica films made by these prior art techniques are never of optical quality because some absorption peaks occur in the 1.30 to 1.55 μm wavelength optical bands. High temperature thermal treatment of the silica films in a dry (nitrogen) ambient is used as in an attempt to reduce the optical absorption of silica films in the 1.30 to 1.55 μm optical region and allow the fabrication of high performance optical quality silica films and optical Multiplexers (Mux) and Demultiplexers (Dmux) with improved performances in the 1.30 bi-directional narrow optical band and/or in the 1.55 μm video signal optical band. High temperature thermal treatment of silica films in a dry (nitrogen) ambient is not, however, a very efficient way to eliminate the various absorption peaks which cause excessive optical absorption in the 1.30 to 1.55 μm optical bands.

Recently published literature indicates that various technical approaches have been tried to obtain high performance optically transparent silicate films.

A first approach is Flame Hydrolysis Deposition (FHD). This technique involves the fusion in hydrogen, oxygen and other gases of fine glass particles followed by some post-deposition anneals to 1200-1350° C. The following articles describe this approach: Suzuki S., Polarization insensitive arrayed-waveguide gratings using dopant-rich silica-based glass with thermal coefficient adjusted to silicon substrate, Electron. Lett. 33 (13), 1173, 1997; Takahashi H., Polarization-insensitive arrayed waveguide wavelenght multiplexer with birefringence compensating film, IEEE Photon. Tech. Lett. 5 (6), 707, 1993; and Kawachi M., Silica waveguides on silicon and their application to integrated-optic components, Optical and quantum Electronics, 22, 391, 1990

A second approach is the High Pressure Steam (HPS) technique. This technique involves the direct growth of silicate films from silicon under an oxygen containing ambient at very high temperature followed by a very high temperature anneal at about 1000° C. This approach is described in: Verbeek B., Integrated four-channel Mach-Zehnder multi-demultiplexer fabricated with phosphorus doped SiO2 waveguides on Si, J. Lightwave tech., 6 (6), 1011, 1988; Henry C., Four-channel wavelength division multiplexers and bandpass filters on elliptical Bragg reflectors, J. Lightwave tech., 8 (5), 748, 1990; and Adar R., Less than 1 dB per meter propagation loss of silica waveguides measured using a ring oscillator, J. Lightwave tech., 12 (8), 1369, 1994.

A third approach is the Electron-Beam Vapor Deposition (EBVD) technique of quartz or silica at about 350° C. followed by very high temperature anneals at 1200° C. See, for example, Imoto K., Silica Glass waveguide structure and its implication to a multi/demultiplexer, ECOC, 577, 1988; and Imoto K., High-silica guided-wave optical devices, 41^{st} ECTC, 483, 1991

A fourth approach is to use Plasma Enhanced Chemical Vapour Deposition (PECVD) to achieve optical quality silica waveguides with reduced optical absorption of in the 1.30 to 1.55 μm optical region. See, for example, Lam D. K. W., Low temperature plasma chemical vapor deposition of silicon oxynitride thin-film waveguides, Applied Optics, 23 (16), 2744, 1984; Valette S., New integrated optical multiplexer-demultiplexer realized on silicon substrate, ECIO '87, 145, 1987; Grand G., Low-loss PECVD silica channel waveguides for optical communications, Electron. Lett., 26 (25), 2135, 1990; Bruno F., Plasma-enhanced chemical vapor deposition of low-loss SiON optical waveguides at 1.5-μm wavelength, Applied Optics, 30 (31), 4560, 1991; Kasper K., Rapid deposition of high-quality silicon-oxynitride waveguides, IEEE Trans. Photonics Tech. Lett., 3 (12), 1096, 1991; Lai Q., Simple technologies for fabrication of low-loss silica waveguides, Elec. Lett., 28 (11), 1000, 1992; Bulat E. S., Fabrication of waveguides using low-temperature plasma processing techniques, J. Vac. Sci. Technol. A 11 (4), 1268, 1993; Imoto K., High refractive index difference and low loss optical waveguide fabricated by low temperature processes, Electron. Lett., 29 (12), 1123, 1993; Bazylenko M. V., Fabrication of low-temperature PECVD channel waveguides with significantly improved loss in the 1.50-1.55 μm wavelength range, IEEE Ptotonics Tech. Lett., 7 (7), 774, 1995; Liu K., Hybrid optoelectronic digitally tunable receiver, SPIE, Vol 2402, 104, 1995; Yokohama S., Optical waveguide on silicon chips, J. Vac. Sci. Technol. A, 13 (3), 629, 1995; Hoffmann M., Low temperature, nitrogen doped waveguides on silicon with small core dimensions fabricated by PECVD/RIE, ECIO'95, 299, 1995; Bazylenko M. V., Pure and fluorine-doped silica films deposited in a hollow cathode reactor for integrated optic applications, J. Vac. Sci. Technol. A 14 (2), 336, 1996; Durandet A., Silica burried channel waveguides fabricated at low temperature using PECVD, Electronics Letters, 32 (4), 326, 1996; Poenar D., Optical properties of thin film silicon-compatible materials, Appl. Opt. 36 (21), 5122, 1997; Agnihotri O. P., Silicon oxynitride waveguides for optoelectronic integrated circuits, Jpn. J. Appl. Phys., 36, 6711, 1997; Boswell R. W., Deposition of silicon dioxide films using the helicon diffusion reactor for integrated optics applications, Plasma processing of semiconductors, Klumer Academic Publishers, 433, 1997; Hoffmann M., Low-loss fiber-matched low-temperature PECVD waveguides with small-core dimensions for optical communication systems, IEEE Photonics Tech. Lett., 9 (9), 1238, 1997; Pereyra I., High quality low temperature DPECVD silicon dioxide, J. Non-Crystalline Solids, 212, 225, 1997; Kenyon T., A luminescence study of silicon-rich silica and rare-earth doped silicon-rich silica, Fourth Int. Symp. Quantum Confinement Electrochemical Society, 97-11, 304, 1997; Alayo M., Thick SiOxNy and SiO2 films obtained by PECVD technique at low temperatures, Thin Solid Films, 332,40, 1998; Bulla D., Deposition of thick TEOS PECVD silicon oxide layers for integrated optical waveguide applications, Thin Solid Films, 334, 60, 1998; Valette S., State of the art of integrated optics technology at LETI for achieving passive optical components, J. of Modern Optics, 35 (6), 993, 1988; Ojha S., Simple method of fabricating polarization-insensitive and very low crosstalk AWG grating devices, Electron. Lett., 34 (1), 78, 1998; Johnson C., Thermal annealing of waveguides formed by ion implantation of silica-on-Si, Nuclear Instruments and Methods in Physics Research, B141, 670, 1998; Ridder R., Silicon oxynitride planar waveguiding structures for application in optical communication, IEEE J. of Sel. Top. In Quantum Electron., 4 (6), 930, 1998; Germann R., Silicon-oxynitride layers for optical waveguide applications, 195^{th} meeting of the Electrochemical Society, 99-1, May 1999, Abstract 137, 1999; Worhoff K., Plasma enhanced cyhemical vapor deposition silicon oxynitride optimized for application in integrated optics, Sensors and Actuators, 74, 9, 1999; and Offrein B., Wavelength tunable optical add-after-drop filter with flat passband for WDM networks, IEEE Photonics Tech. Lett., 11 (2), 239, 1999.

A comparison of these PECVD references is shown in Table 1, which summarises the various PECVD approaches and the reported method used to control the refractive index and to reduce the optical absorption of silica films. The various PECVD approaches can be grouped into the following categories: Unknown PECVD reactions to reduce the optical absorption and involving B and/or P to adjust the refractive index of the silica films; PECVD using TEOS but with no details on the technique used to reduce the optical absorption and adjust the refractive index of the silica films; PECVD using oxidation of SiH₄ using O₂ but no details on the technique used to simultaneously reduce the optical absorption and adjust the refractive index of the silica films; PECVD using oxidation of SiH₄ using O₂ and CF₄ with SiH₄/O₂ flow ratio to reduce the optical absorption and SiH₄/O₂/CF₄ flow ratio to adjust the refractive index of the silica films; PECVD using oxidation of SiH₄ using N₂O with SiH₄/N₂O flow ratio to simultaneously reduce the optical absorption and adjust the refractive index of the silica films; PECVD using oxidation of SiH₄ using N₂O and N₂ with SiH₄/N₂O/N₂ flow ratio to reduce the optical absorption and to adjust the refractive index of the silica films; PECVD using oxidation of SiH₄ using N₂O and Ar with SiH₄/N₂O/Ar flow ratio to reduce the optical absorption and to adjust the refractive index of the silica films; and PECVD using oxidation of SiH₄ using N₂O and NH₃ with SiH₄/N₂O flow ratio to reduce the optical absorption and SiH₄/N₂O/NH₃ flow to adjust the refractive index of the silica films.

TABLE 1

| | | Deposition |
|---|---|---|
| Publication | PECVD Reaction | Control Method |
| Valette S., 1987 | Unknown | Content in Si, P |
| Valette S., 1988 | Unknown | Content in Si, P |
| Grand G., 1990 | Unknown | Content in Si, P |
| Liu K., 1995 | Unknown | Content in Si, P |
| Qjha S., 1998 | Unknown | Content in Si, B, P |
| Bulla D., 1998 | TEOS | TEOS |
| Johnson C., 1998 | SiH₄ + O₂ | Unknown |
| Bazylenko M. V., | SiH₄ + O₂ + CF₄ | SiH₄/O₂/CF₄ flow ratio |
| 1995 | | |
| Bazylenko M. V., | SiH₄ + O₂ + CF₄ | SiH₄/O₂/CF₄ flow ratio |
| 1995 | | |
| Bazylenko M. V., | SiH₄ + O₂ + CF₄ | SiH₄/O₂/CF₄ flow ratio |
| 1996 | | |
| Durandet A., 1996 | SiH₄ + O₂ + CF₄ | SiH₄/O₂/CF₄ flow ratio |
| Boswell R. W., | SiH₄ + O₂ + CF₄ | SiH₄/O₂/CF₄ flow ratio |
| 1997 | | |
| Kasper K., 1991 | SiH₄ + N₂O | SiH₄/N₂O flow ratio |
| Lai Q., 1992 | SiH₄ + N₂O | SiH₄/N₂O flow ratio |
| Pereyra I., 1997 | SiH₄ + N₂O | SiH₄/N₂O flow ratio |
| Alayo M., 1998 | SiH₄ + N₂O | SiH₄/N₂O flow ratio |
| Imoto K., 1993 | SiH₄ + N₂ O + N₂ | SiH₄/N₂O/N₂ flow ratio |
| This Patient | SiH₄ + N₂O + N₂ | Patented Method |
| Kenyon T., 1997 | SiH₄ + N₂O + Ar | SiH₄/N₂O/Ar flow ratio |
| Lam D. K. W., | SiH₄ + N₂O + NH₃ | SiH₄/N₂O/NH₃ flow ratio |
| 1984 | | |
| Bruno F., 1991 | SiH₄ + N₂O + NH₃ | SiH₄/N₂O/NH₃ flow ratio |
| Yokohama S., 1995 | SiH₄ + N₂O + NH₃ | SiH₄/N₂O/NH₃ flow ratio |
| Agnihotri O. P., | SiH₄ + N₂O + NH₃ | SiH₄/N₂O/NH₃ flow ratio |
| 1997 | | |
| Germann R., 1999 | SiH₄ + N₂O + NH₃ | Unknown |
| Offrein B., 1999 | SiH₄ + N₂O + NH₃ | Unknown |
| Hoffmann M., 1995 | SiH₄ + N₂O + NH₃ + Ar | SiH₄/N₂O/NH₃/Ar flow |
| | | ratio |
| Hoffmann M., 1997 | SiH₄ + N₂O + NH₃ + Ar | SiH₄/N₂O/NH₃/Ar flow |
| | | ratio |
| Poenar D., 1997 | SiH₄ + N₂O + NH₃ + N₂ | SiH₄/N₂O/NH₃/N₂ flow |
| | | ratio |
| Ridder R., 1998 | SiH₄ + N₂O + NH₃ + N₂ | SiH₄/N₂O/NH₃/Ar flow |
| | | ratio |
| Worhoff K., 1999 | SiH₄ + N₂O + NH₃ + N₂ | SiH₄/N₂O/NH₃/N₂ flow |
| | | ratio |
| Bulat E. S., 1993 | SiH₄ + N₂O + N₂ + CF₄ | SiH₄/N₂O/N₂/CF₄ flow |
| | | ratio |

FTIR spectra of optical quality silica films are characterized by the presence of only four optical absorption peaks. Generally the objective in producing optical quality films is to produce FTIR spectra only showing the four infrared absorption peaks of optical quality silica films. These peaks consists of an intense and small Full Width at Half Maximum (FWHM) Si—O—Si “rocking mode” absorption peak ranging between 410 and 510 cm⁻¹, centred at 460 cm⁻¹ (21.739 μm); a small FWHM Si—O—Si “bending mode” absorption peak ranging between 740 and 880 cm⁻¹, centred at 810 cm⁻¹ (12.346 μm); a very intense and small Full Width at Half Maximum (FWHM) Si—O—Si “in-phase-stretching mode” absorption peak ranging between 1000 and 1160 cm⁻¹, centred at 1080 cm⁻¹ (9.256 μm) indicating stoichiometric silica films with the optimum Si—O—Si bond angle of 144° and the optimum density; and an Si—O—Si “out-of-phase-stretching mode” absorption peak ranging between 1080 and 1280 cm⁻¹, centred at 1180 cm⁻¹ (8.475 μm), as compared to the Si—O—Si in-phase-stretching mode absorption peak. This latter peak should be almost eliminated.

The position in the infrared spectra of these four fundamental mode absorption peaks, respectively centered at 21.739 μm, 12.346 μm, 9.256 μm and 8.475 μm, is far away from the infrared band of interest which ranges from 1.30 to 1.55 μm. Residual absorption of optical quality silica is never completely eliminated because the higher harmonics of these four fundamental residual absorption peaks do cause small residual optical absorption peaks in the 1.30 to 1.55 μm optical band. This residual absorption of optical quality silica is so small that many km of silica optical fiber can be used with negligible absorption in this optical band. This is explained by the fact that only the very high harmonics of these four residual absorption peaks do fall in the 1.30 to 1.55 μm optical band, namely the sixth (1.302 to 1.543 μm) and seventh (1.116 to 1.323 μm) harmonics of the Si—O—Si “out-of-phase-stretching mode” infrared absorption peak; the sixth (1.437 to 1.667 μm) and seventh (1.232 to 1.429 μm) harmonics of the Si—O—Si “in-phase-stretching mode” infrared absorption peak; the eighth (1.420 to 1.689 μm) and ninth (1.263 to 1.502 μm) harmonics of the Si—O—Si “bending mode” infrared absorption peak; and the thirteenth (1.508 to 1.876 μm), fourteenth (1.401 to 1.742 μm) and fifteenth (1.307 to 1.626 μm) harmonics of the Si—O—Si “rocking mode” infrared absorption peak.

The FTIR spectra of optical quality silica films are also characterized by a net separation between the Si—O—Si “in-phase-stretching mode” absorption peak (1080 cm⁻¹) and the Si—O—Si “bending mode” absorption peak (810 cm⁻¹) with a deep valley between 850 and 1000 cm⁻¹.

Such optical quality silica films are extremely difficult to produce because residual hydrogen and nitrogen atoms are typically present in the films. In reality FTIR spectra also show other infrared absorption peaks having higher harmonics in the 1.30 to 1.55 μm optical bands. As mentioned before, various PECVD approaches can be used to control the refractive index and to reduce the optical absorption of the deposited silica films. The expected result is an optical quality silica with the expected infrared transmission spectra. Fourier Transformed Infrared Reflectance, FTIR, spectroscopy can monitor the quality of the obtained silica films.

The High temperature thermal treatments also have their own shortcomings. Optical quality silica films typically require a post-deposition thermal treatment at a high temperature as high as 1350° C. in order to eliminate residual optical absorption peaks in the 1.30 to 1.55 μm optical region.

An object of the invention is to provide an improved technique for producing optical quality silica films.

### SUMMARY OF THE INVENTION

The invention provides a technique for depositing silica films that uses Plasma Enhanced Chemical Vapour Deposition, but which results in a better elimination of undesirable residual Si:N—H oscillators (observed as a FTIR peak centered at 3380 cm⁻¹) after thermal treatment at lower post-deposition temperature to provide improved optical quality silica waveguides with reduced optical absorption of in the 1.30 to 1.55 μm optical region. Such waveguides are suitable for use in the fabrication of high performance optical quality Multiplexers (Mux) and Demultiplexers (Dmux) with improved performances in the 1.30 bi-directional narrow optical band and/or in the 1.55 μm video signal optical band.

The fabrication of improved PECVD optical quality silica films can be achieved using a commercially available PECVD system, for example, the “Concept One” system manufactured by Novellus Systems in California, USA. The optical quality silica films in accordance with the invention are obtained using a lower temperature post-deposition thermal treatment due to an improved PECVD deposition technique. The present invention permits the deposition of improved silica films that result in a better elimination of the undesirable residual Si:N—H oscillators (observed as a FTIR peak centered at 3380 cm⁻¹) after thermal treatments at lower post-deposition temperature to provide improved optical quality silica waveguides with reduced optical absorption of in the 1.30 to 1.55 μm optical region in order to use them in the fabrication of high performance optical quality Multiplexers (Mux) and Demultiplexers (Dmux) with improved performances in the 1.30 bi-directional narrow optical band and/or in the 1.55 μm video signal optical band.

Accordingly, in one aspect of the present invention a method of depositing an optical quality silica film on a substrate, comprising forming said optical quality silica film on said substrate by plasma enhanced chemical vapor deposition (PECVD) in the presence of gases while controlling the total pressure of said gases; and subjecting the as-deposited film to a low temperature treatment between 400° to 1200° C. to minimize the presence of contaminant compounds in said film.

Generally, the total pressure should be controlled to minimize the presence of Si—Oₓ—H_{y}—Nz compounds after the low temperature treatment.

The preferred temperature for low temperature post treatment is about 800° C. and the preferred temperature range for the total gas pressure is 2.0 to 2.6 Torr, with 2.4 Torr being the preferred pressure.

The preferred deposition temperature is between 100 and 650° C., with about 400° C. being the most preferred value.

Typically the deposition is carried out with SiH₄ as a raw material gas N₂O as an oxidation gas is, N₂ as a carrier gas, although other materials can be used.

Optimally, the flow rate of the SiH₄ is about 0.2 std liter/min., the flow rate of the N₂O is about 6.00 std liter/min., and the flow rate of the N₂ is about 3.15 std liter/min.

In another aspect the invention provides a method of depositing an optical quality silica film on a substrate, comprising forming said optical quality silica film on said substrate at a temperature between 100 and 650° C. by plasma enhanced chemical vapor deposition (PECVD) in the presence of a raw material gas, an oxidation gas, and a carrier gas while controlling the total pressure of said gases to a pressure of between 2.0 to 2.6 Torr; and subjecting the as-deposited film to a low temperature treatment at about 800° C. to minimize the presence of Si—Oₓ—H_{y}—Nz compounds after said low temperature treatment.

The novel PECVD approach in accordance with the invention can provide undoped (no B and/or P) silica films from the oxidation of silane, SiH₄, using nitrous oxide, N₂O. It will then focus on the effect of additional nitrogen, N₂, reactant gas.

This discussion will not consider means of adding ammonia, NH₃, fluorine, F, phosphorus, P, boron, B, or other compounds or elements as a way to control refractive indexes.

It will be understood by one skilled in the art that the invention is not limited to the specific PECVD chemistries described and that other chemistries may be employed.

### BRIEF DESCRIPTION OF THE DRAWINGS

The invention will now be described in more detail, by way of example only, with reference to the accompanying drawings, in which:

FIG. 1 is a table showing the various Si—Oₓ—H_{y}—N_{z} as-deposited compounds that may result from the combinations of a silane (SiH4) and nitrous oxide (N2O) gas mixture;

FIG. 2 is a table showing the chemical reactions of the thirty-five (35) as-deposited compounds that could be found in silica films deposited from a silane (SiH₄) and nitrous oxide (N₂O) gas mixture;

FIG. 3 is a table listing the possible chemical reactions that may result from the exposure of the thirty-five (35) as-deposited compounds to nitrogen at very high temperature;

FIG. 4 shows the FTIR fundamental infrared absorption peaks and their corresponding higher harmonics peaks associated with the six (6) residual potential post-treatment compounds that result from a high temperature thermal treatment of silica films in a nitrogen ambient;

FIG. 5a shows the basic FTIR spectra of PECVD silica films before and after a three hours long high temperature thermal treatment in a nitrogen ambient at a temperature of either 600, 700, 800, 900, 1000 or 1100° C.;

FIG. 5b shows the basic FTIR spectra of silicon films obtained with the improved PECVD deposition technique after a three hours long high temperature thermal treatment in a nitrogen ambient at a low temperature of 800° C.;

FIG. 6a shows the in-depth FTIR spectra from 810 to 1000 cm⁻¹ of PECVD silica films before and after a three hours long high temperature thermal treatment in a nitrogen ambient at a temperature of either 600, 700, 800, 900, 1000 or 1100° C.;

FIG. 6b shows the in-depth FTIR spectra from 810 to 1000 cm⁻¹ of silica films obtained with the improved deposition technique after a three hour long high temperature thermal treatment in a nitrogen ambient at a low temperature of 800° C.;

FIG. 7a shows the in-depth FTIR spectra from 1500 to 1600 cm⁻¹ of PECVD silica films before and after a three hours long high temperature thermal treatment in a nitrogen ambient at a temperature of either 600, 700, 800, 900, 1000 or 1100° C.;

FIG. 7b shows the in-depth FTIR spectra from 1500 to 1600 cm⁻¹ of silica films obtained with the improved PECVD deposition technique after a three hours long high temperature thermal treatment in a nitrogen ambient at a low temperature of 800° C.;

FIG. 8a shows the in-depth FTIR spectra from 1700 to 2200 cm⁻¹ of PECVD silica films before and after a three hours long high temperature thermal treatment in a nitrogen;

FIG. 8b shows the in-depth FTIR spectra from 1700 to 2200 cm⁻¹ of silica films obtained with the improved PECVD deposition technique after a three hours long high temperature;

thermal treatment in a nitrogen ambient at a low temperature of 800° C.;

FIG. 9a shows the in-depth FTIR spectra from 2200 to 2400 cm⁻¹ of PECVD silica films before and after a three hours long high temperature thermal treatment in a nitrogen;

FIG. 9b shows the in-depth FTIR spectra from 2200 to 2400 cm⁻¹ of silica films obtained with the improved PECVD deposition technique after a three hours long high temperature thermal treatment in a nitrogen ambient at a low temperature of 800° C.;

FIG. 10a shows the in-depth FTIR spectra from 3200 to 3900 cm⁻¹ of PECVD silica films before and after a three hours long high temperature thermal treatment in a nitrogen;

FIG. 10b shows the in-depth FTIR spectra from 3200 to 3900 cm⁻¹ of silica films obtained with the improved PECVD deposition technique after a three hours long high temperature thermal treatment in a nitrogen ambient at a low temperature of 800° C.;

FIG. 11 shows the effect of the total deposition pressure on the integrated area under the 3380 cm⁻¹ FTIR peak of the Si:N—H oscillators of PECVD silica films deposited at a fixed SiH₄ gas flow of 0.20 std liter/min, at a fixed N₂O gas flow of 6.00 std liter/min, at a fixed N₂ gas flow of 3.15 std liter/min and following a thermal treatment in a nitrogen ambient at 800° C.;

FIG. 12 shows the effect of the total deposition pressure on the 1.55 μm refractive index of PECVD silica films deposited at a fixed SiH₄ gas flow of 0.20 std liter/min, at a fixed N₂O gas flow of 6.00 std liter/min, at a fixed N₂ gas flow of 3.15 std liter/min and following a thermal treatment in a nitrogen ambient at 800° C.;

FIG. 13 shows the effect of the N2O gas flow on the 1.55 μm refractive index of PECVD silica films deposited at a fixed SiH4 gas flow of 0.20 std liter/min, at a fixed N2 gas flow of 3.15 std liter/min, at a fixed total deposition pressure of 2.60 Torr and following a thermal treatment in a nitrogen ambient at 800° C.; and

FIG. 14 shows the effect of the N₂O gas flow on the 1.55 μm refractive index of PECVD silica films deposited at a fixed SiH₄ gas flow of 0.20 std liter/min, at a fixed N₂ gas flow of 3.15 std liter/min, at a fixed total deposition pressure of 2.60 Torr and following a thermal treatment in a nitrogen ambient at 800° C.

### DETAILED DESCRIPTION OF THE PREFERRED EMBODIMENTS

The deposition of silica films by PECVD from a silane, SiH₄, and nitrous oxide, N₂O, gas mixture at a relatively low temperature of 400° C. is typically described by the following reaction:

SiH₄(g)+2N₂O(g)→SiO₂ +2N₂(g)+2H₂(g)

This chemical reaction shows that it should theoretically be possible to achieve optical quality silica films directly from silane and nitrous oxide. This would be true if this was really the only chemical reaction involved in the deposition of the silica films.

In reality the incorporation of oxygen atoms, a key factor to achieve optical quality silica, competes with the incorporation of nitrogen and hydrogen atoms in the silica films. At a microscopic scale, the local incorporation of nitrogen and hydrogen atoms results in a mixture of a considerable number of undesirable Si—Oₓ—H_{y}—N_{z} as-deposited compounds that are bonded to each other as to form the deposited silica films.

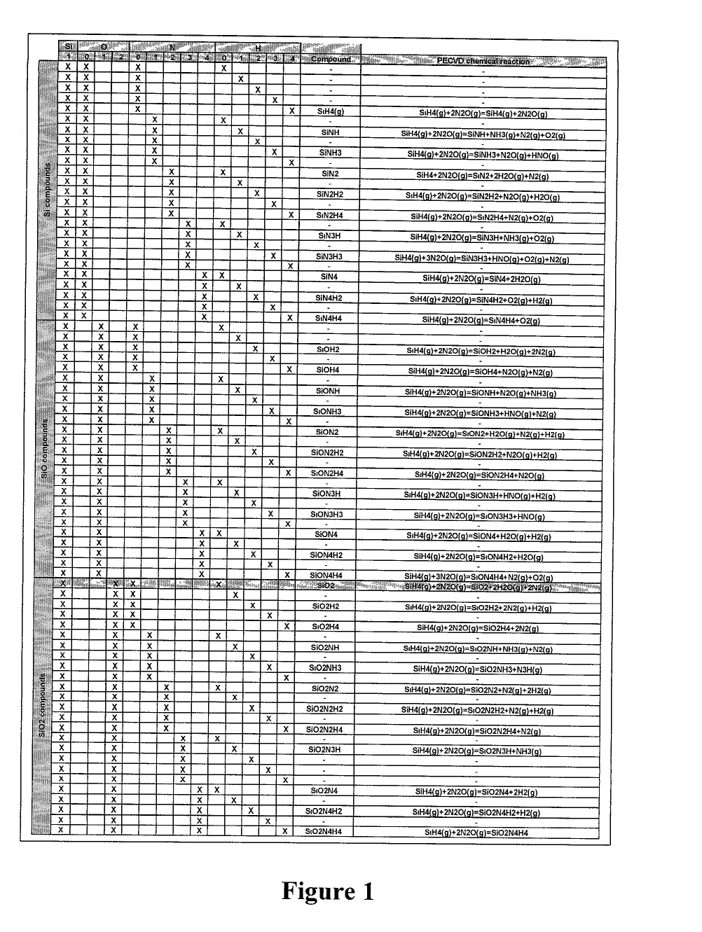

FIG. 1 lists the various Si—Oₓ—H_{y}—N_{z} possible as-deposited compounds that may result from the combinations of a silane (SiH₄) and nitrous oxide (N₂O) gas mixture. It shows seventy-five (75) combinations of potential as-deposited compounds: 0 to 2 oxygen atoms (3 combinations); 0 to 4 nitrogen atoms (5 combinations); and 0 to 4 hydrogen atoms.(5 combinations).

Only thirty-five (35) of these seventy-five (75) combinations can actually form potential as-deposited compounds that can accommodate the chemical bonds of their constituting atoms: 4 chemical bonds for silicon; 2 chemical bonds for oxygen; 3 chemical bonds for nitrogen; and 1 hydrogen bond for hydrogen.

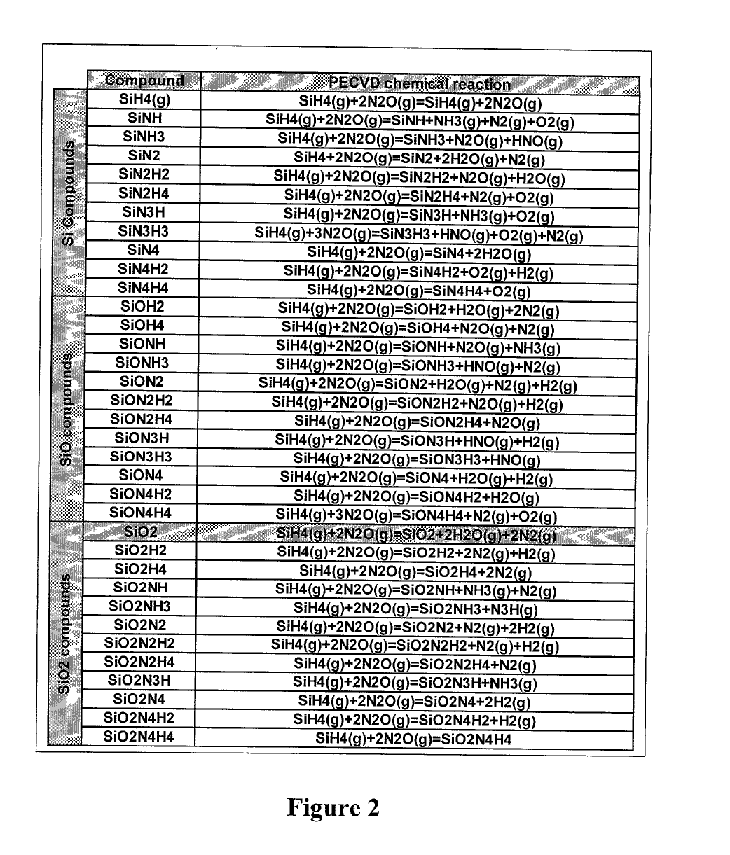

FIG. 2 lists the chemical reactions of the thirty-five (35) potential as-deposited compounds that could form in silica films deposited from a silane (SiH₄) and nitrous oxide (N₂O) gas mixture. During these chemical reactions, it is clear that N₂,O₂, HNO, NH₃, H₂O, and H₂ gaseous compounds must be eliminated from the micro-pores of the growing silica films up to their surface and from their surface through the gaseous boundary layer present near their surface. It is also clear that many of these chemical reactions involve a modification of the number of gaseous compounds; i.e. that the number of gaseous product compound molecules is different than three, the number of gaseous reactant compound molecules. Then, the fundamentals of classical thermodynamics predict that the equilibrium constants of these many chemical reactions will be affected by the total deposition pressure and that the optimization of the silica films requires more then just controlling the ratio of silane-to-nitrous oxide gas flow ratios.

The obtained silica films are the result of these competing chemical reactions and are composed of a mixture of these various Si—Oₓ—H_{y}—N_{z} potential as-deposited compounds. To these potential as-deposited compounds are associated inter-atomic oscillators which can be detected by FTIR as absorption peaks which are different from the four characteristic peaks of ideal optical silica films. Some of these extra absorption peaks do have a higher harmonics mode that cause optical absorption in the 1.30 to 1.55 μm optical bands. For that reason, the prior art uses a post-deposition high temperature thermal treatment of silica films in a dry (nitrogen) ambient at a temperature ranging between 600 and 1350° C. in an attempt eliminate these extra absorption peaks in the 1.30 to 1.55 μm optical region.

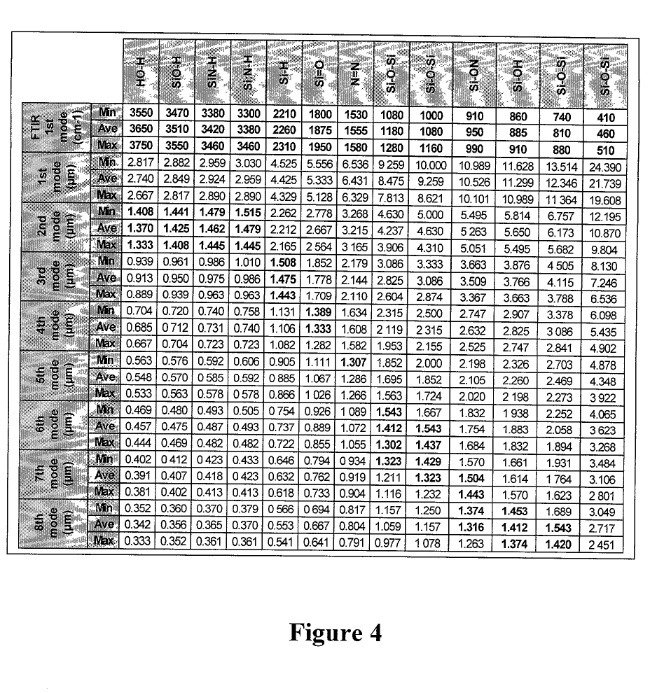

FIG. 4 lists the possible chemical reactions (i.e. thermal decomposition reactions) that may result from the exposure of the thirty-five (35) potential as-deposited compounds to nitrogen at very high temperature. Again, the thermal decomposition reactions (producing a potential post-treatment compound after the high temperature thermal treatment which is different then the potential as-deposited compound before high temperature thermal treatment) have to preserve the need to accommodate the chemical bonds of their constituting atoms. These various reactions present a very clear overview of the limitations of these high temperature thermal treatments:

Only twelve (12) of the thirty-five (35) Si—Oₓ—H_{y}—N_{z} potential as-deposited compounds can lead to the formation of SiO₂ during a high temperature thermal treatment in a nitrogen ambient with gaseous by-products such as: nitrogen, N₂, hydrogen, H₂, and ammonia, NH₃.

Following a high temperature thermal treatment in a nitrogen ambient, the other twenty-three (23) Si—Oₓ—H_{y}—N_{z} potential as-deposited compounds can lead to the formation of a short list of five (5) other potential post-treatment compounds: SiNH (no O incorporated in the potential as-deposited compound); SiN₂ (no O incorporated in the potential as-deposited compound); SiOH₂ (one O incorporated in the potential as-deposited compound); SiONH (one O incorporated in the potential as-deposited compound); and SiON₂ (one O incorporated in the potential as-deposited compound).

It is important to realize that high temperature thermal treatment in a nitrogen ambient produces thermal decomposition reactions which are incapable of transforming the twenty-three (23) potential Si—Oₓ—H_{y}—N_{z} as-deposited compounds that result, from a lack of oxygen incorporation into SiO₂, in the other five potential post-treatment compounds. It is then also very important to realize that the displacement of the equilibrium constants of these many chemical reactions which result in the formation of these twenty-three (23) oxygen-lacking potential Si—Ox—Hy—Nz as-deposited compounds as a result of a modification of the total deposition pressure will have a definitive effect on the optimization of the silica films and that this effect will allow the deposition of silica films with optical properties not achievable with a more traditional adjustment of the silane-to-nitrous oxide gas flow ratios.

As a result a control of the total deposition pressure independently of the silane-to-nitrous oxide gas flow ratio can have a pronounced effect on the optical properties of silica films following a lower temperature nitrogen thermal treatment.

Since the silica films that result from these high temperature thermal treatments in a nitrogen ambient are solid mixtures of six (6) potential post-treatment compounds: SiO₂, SiNH, SiN₂, SiOH₂, SiONH and SiON₂, the FTIR spectra can be used to verify this hypothesis by monitoring the transformation of these six (6) residual potential post-treatment compounds.

In general the higher the temperature the lower the optical absorption of the silica films but unlike the case for the fused silica optical fibres, which are heated at a temperature exceeding about 2000° C. during the drawing process, the high temperature thermal treatment of the silica films on silicon wafers is performed at a much lower temperature of less then about 1350° C., the fusion point of the silicon wafer. The thermal treatment temperature is also typically limited by the high compressive mechanical stress induced in the silica films from the difference of thermal expansion between the silica films and the underlying silicon wafer.

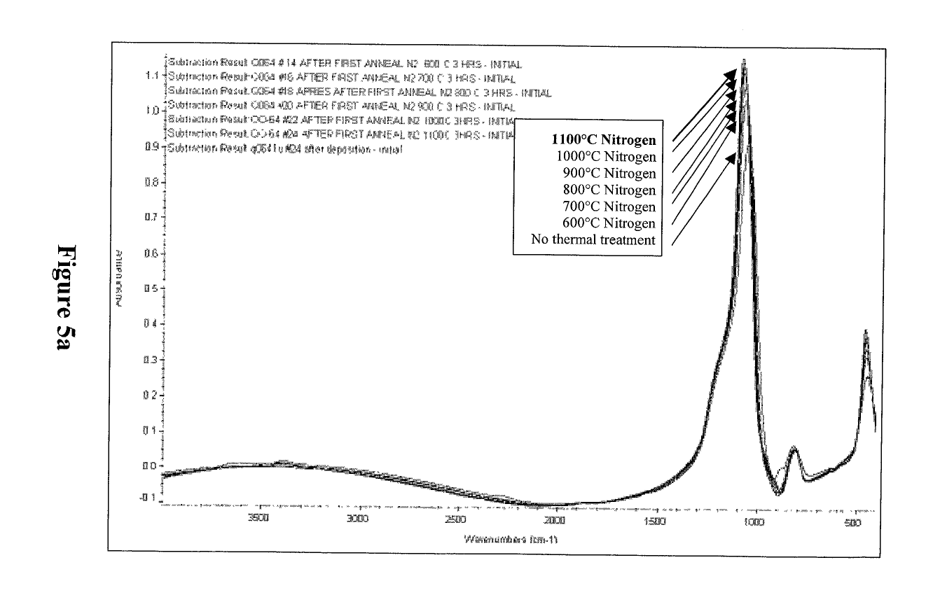

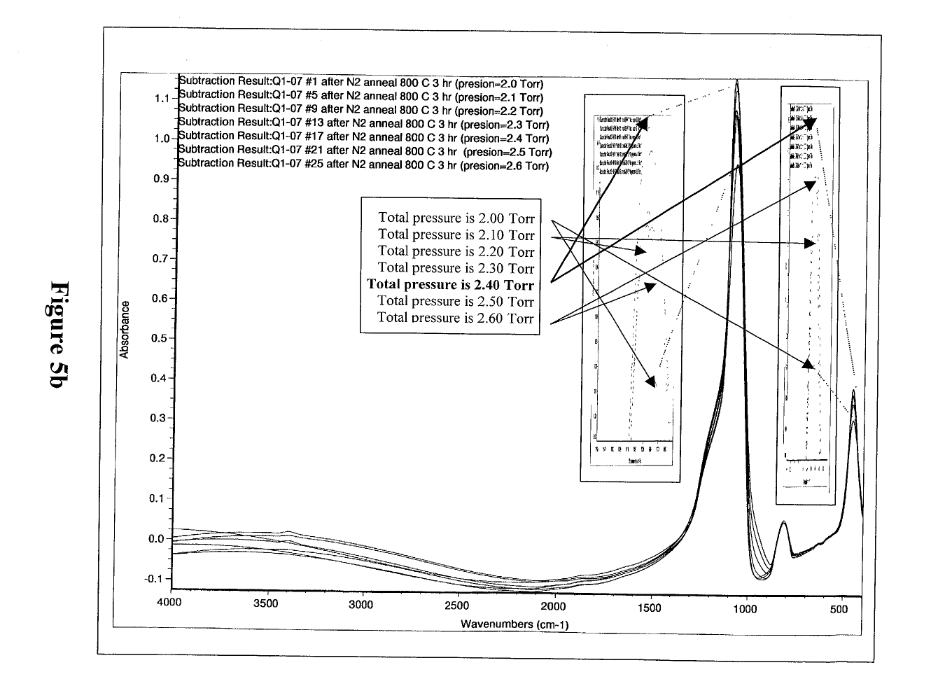

FIG. 5 lists some FTIR fundamental infrared absorption peaks and their corresponding higher harmonics peaks associated with the six (6) residual potential post-treatment compounds that result from thermal decomposition during a high temperature thermal treatment of these silica films in a nitrogen ambient. It is clear from FIG. 5 that the higher harmonics of the absorption peaks corresponding to these six (6) residual potential post-treatment compounds contribute to the optical absorption in the 1.30 to 1.55 μm optical bands. The six peaks are: the second vibration harmonics of the HO—H oscillators in trapped water vapour in the micro-pores of the silica films (3550 to 3750 cm⁻¹), which increase the optical absorption near 1.333 to 1.408 μm; the second vibration harmonics of the SiO—H oscillators in the silica films (3470 to 3550 cm⁻¹), which increase the optical absorption near 1.408 to 1.441 μm; the second vibration harmonics of the Si:N—H oscillators in the silica films (3300 to 3460 cm⁻¹), which increase the optical absorption near 1.445 to 1.515 μm; the second vibration harmonics of the SiN—H oscillators in the silica films (3380 to 3460 cm⁻¹), which increase the optical absorption near 1.445 to 1.479 μm; the third vibration harmonics of the Si—H oscillators in the silica films (2210 to 2310 cm⁻¹), which increase the optical absorption near 1.443 to 1.505 μm; the fourth vibration harmonics of the Si═O oscillators in the silica films (1800 to 1950 cm⁻¹), which increase the optical absorption near 1.282 to 1.389 μm; and the fifth vibration harmonics of the N═N oscillators in the silica films (1530 to 1580 cm⁻¹), which increase the optical absorption near 1.266 to 1.307 μm.

The negative effects of these the oscillators on the optical properties of silica films are reported in the literature. Examples of relevant literature articles are: Grand G., Low-loss PECVD silica channel waveguides for optical communications, Electron. Lett., 26 (25), 2135, 1990; Bruno F., Plasma-enhanced chemical vapor deposition of low-loss SiON optical waveguides at 1.5-μm wavelength, Applied Optics, 30 (31), 4560, 1991; Imoto K., High refractive index difference and low loss optical waveguide fabricated by low temperature processes, Electronic Letters, 29 (12), 1993; Hoffmann M., Low temperature, nitrogen doped waveguides on silicon with small core dimensions fabricated by PECVD/RIE, ECIO'95, 299, 1995; Bazylenko M., Pure and fluorine-doped silica films deposited in a hollow cathode reactor for integrated optic applications, J. Vac. Sci. Technol. A 14 (2), 336, 1996; Pereyra I., High quality low temperature DPECVD silicon dioxide, J. Non-Crystalline Solids, 212, 225, 1997; Kenyon A., A luminescence study of silicon-rich silica and rare-earth doped silicon-rich silica, Electrochem. Soc. Proc. Vol. 97-11,304, 1997; Alayo M., Thick SiOxNy and SiO2 films obtained by PECVD technique at low temperatures, Thin Solid Films, 332, 40, 1998; Worhoff K., Plasma enhanced chemical vapor deposition silicon oxynitride optimized for application in integrated optics, Sensors and Actuators, 74, 9, 1999; and Germann R., Silicon-oxynitride layers for optical waveguide applications, 195^{th} meeting of the Electrochemical Society, 99-1, May 1999, Abstract 137, 1999.

This literature describes the tentative elimination of optical absorption (i.e. of the six residual oscillators) using the discussed thermal decomposition reactions during thermal treatments under a nitrogen ambient at a maximum temperature lower then 1350° C., the fusion point of the silicon wafer. As mentioned, these thermal decomposition reactions in a nitrogen ambient result in a potential of six residual oscillators in the treated silica films which still absorb infrared light in the 1.30 to 1.55 μm optical region.

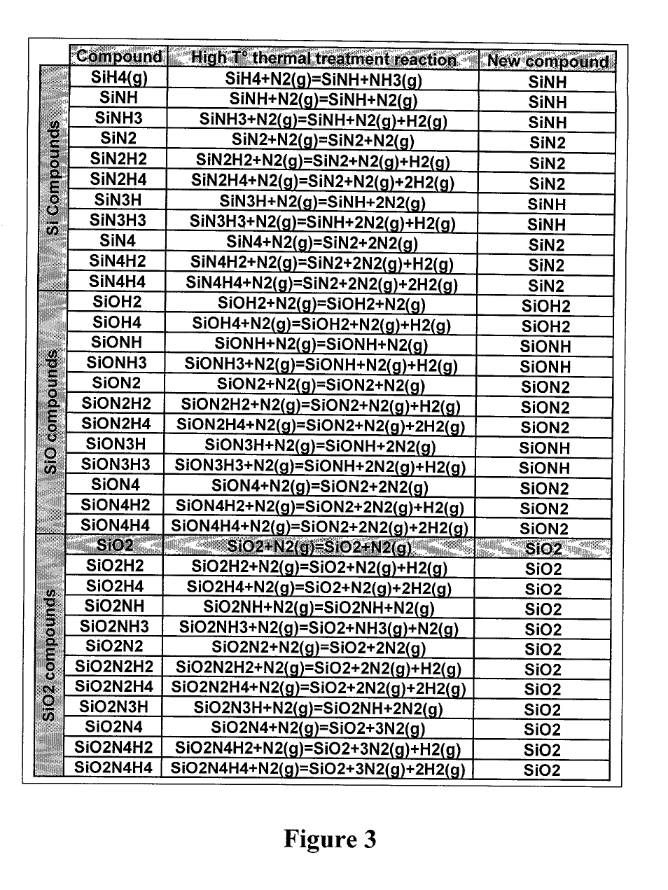

The lack of incorporation of oxygen atoms into the deposition reaction produces, at a microscopic scale, a mixture of the thirty-five (35) undesirable Si—Oₓ—H_{y}—N_{z} potential as-deposited compounds (listed in FIG. 3) difficult to eliminate with temperature treatments.

Twenty-three (23) of these thirty-five (35) undesirable Si—Oₓ—H_{y}—N_{z} potential as-deposited compounds are sub-stoichiometric oxygen compounds (FIG. 4) and this makes it very unlikely that temperature treatments in nitrogen inducing thermal decomposition of these residual as-deposited compounds will result in the required pure silicate, SiO₂, films; i.e. that the thermal decomposition in nitrogen will not likely be able to completely eliminate the five residual undesirable post-treatment compounds: SiNH, SiN₂, SiOH₂, SiONH and SiON₂ associated to the various residual undesirable oscillators which prevent the achievement of optical quality silica waveguides with reduced optical absorption of in the 1.30 to 1.55 μm optical region.

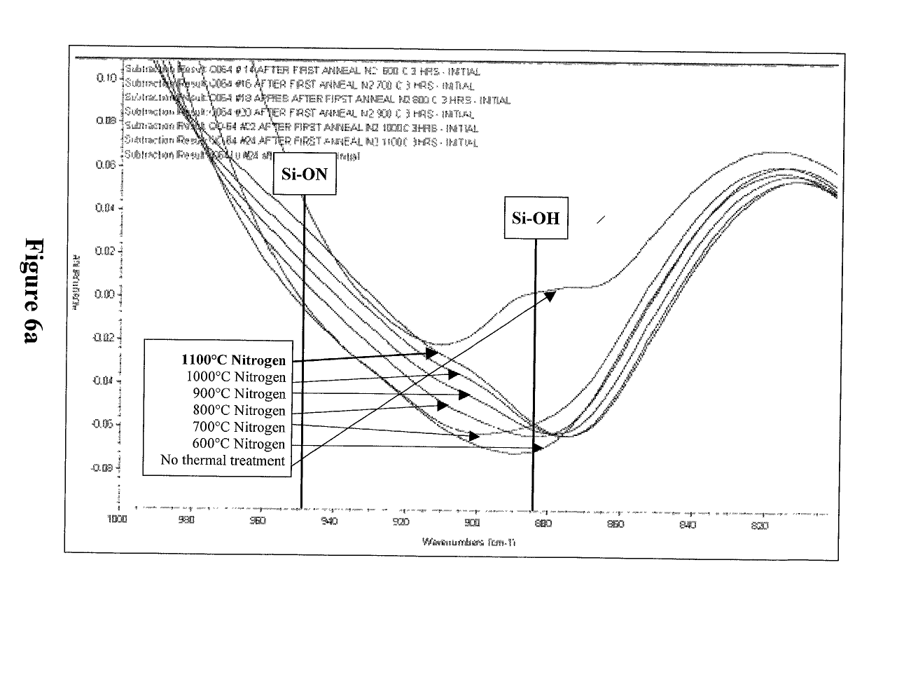

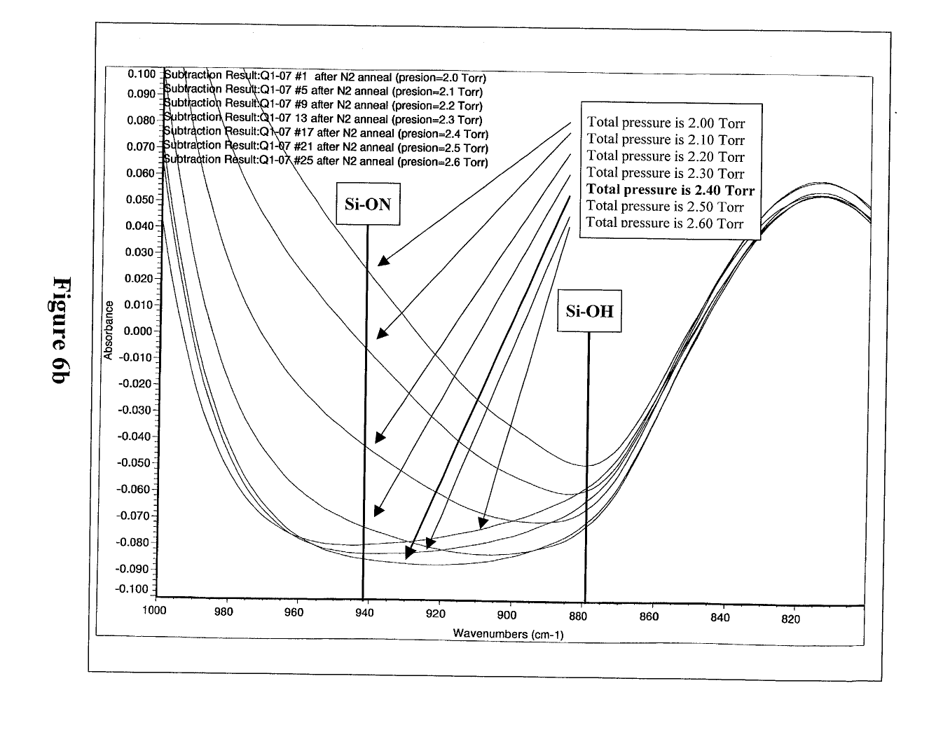

FIG. 6a shows the basic FTIR spectra of typically deposited PECVD silica films before and after a three hours long high temperature thermal treatment in a nitrogen ambient at a temperature of either 600, 700, 800, 900, 1000 or 1100° C. It is clear that the higher the thermal decomposition temperature of the high temperature thermal treatment in a nitrogen ambient, the better the thermal decomposition of silica films, the better the elimination of: nitrogen, N₂, hydrogen, H₂, and ammonia, NH₃. (i.e. as per the chemical reactions of FIG. 4) and the better the FTIR spectra of the treated silica films (i.e. the better the four basic optical absorption peaks):

A more intense and smaller FWHM Si—O—Si “rocking mode” absorption peak ranging between 410 and 510 cm⁻¹;

A smaller FWHM Si—O—Si “bending mode” absorption peak ranging between 740 and 880 cm⁻¹;

A more intense and smaller FWHM Si—O—Si “in-phase-stretching mode” absorption peak ranging between 1000 and 1160 cm⁻¹, indicating a more stoichiometric silica films with the optimum density and optimum Si—O—Si bond angle of 144°;

A gradual elimination of the Si—O—Si “out-of-phase-stretching mode” absorption peak ranging between 1080 and 1280 cm⁻¹, as compared to the Si—O—Si in-phase-stretching mode absorption peak;

A gradual separation between the Si—O—Si “in-phase-stretching mode” absorption peak (1080 cm⁻¹) and the Si—O—Si “bending mode” absorption peak (810 cm⁻¹) with a deeper valley between 850 and 1000 cm⁻¹.

An in-depth examination of some infrared regions of the FTIR spectra of FIG. 6a with the help of the FTIR regions of the table of FIG. 5 helps verify the presence of the six (6) residual potential post-treatment compounds: SiO₂, SiNH, SiN₂, SiOH₂, SiONH and SiON₂ that potentially contribute to the reported residual optical absorption in the 1.30 to 1.55 μm wavelength optical bands.

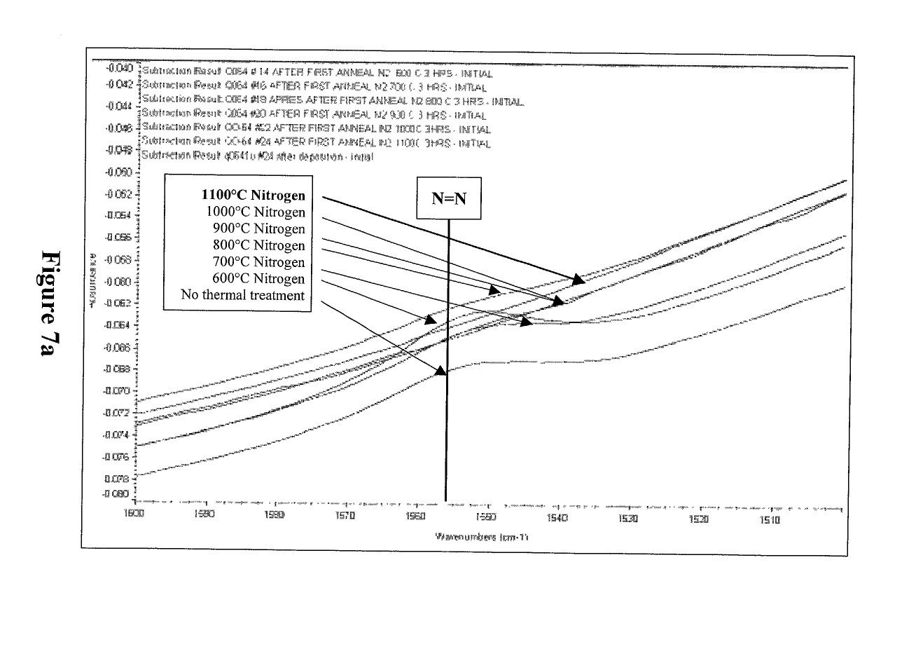

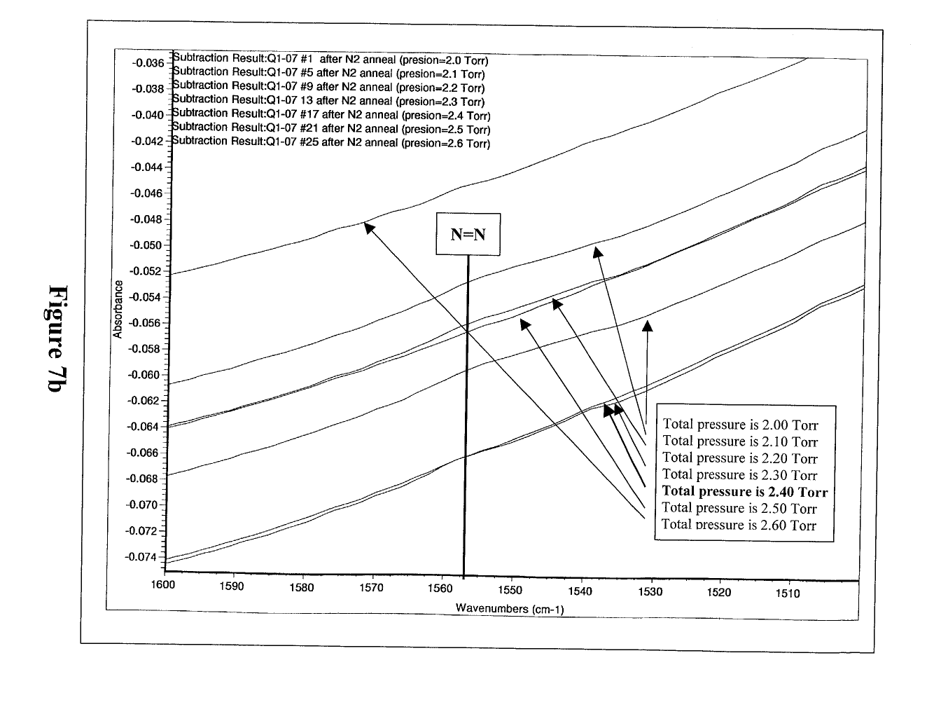

FIG. 7a shows the in-depth FTIR spectra from 810 to 1000 cm⁻¹ of typically deposited PECVD silica films before and after a three hours long high temperature thermal treatment in a nitrogen ambient at a temperature of either 600, 700, 800, 900, 1000 or 1100° C. This region of the FTIR spectra should show a net separation between the Si—O—Si “in-phase-stretching mode” absorption peak (1080 cm⁻¹) and the Si—O—Si “bending mode” absorption peak (810 cm⁻¹) and should show a deep valley between 850 and 1000 cm⁻¹. It is clear that the higher the thermal decomposition temperature of the high temperature thermal treatment in a nitrogen ambient, the better the separation and the deeper the valley. The reduction and gradual elimination of the Si—OH oscillators, centered at 885 cm⁻¹ (i.e. of some configurations of the SiOH₂ residual potential post-treatment compounds) using various chemical reactions of FIG. 4 is demonstrated to occur following the 600° C. thermal treatment in a nitrogen ambient. A residual peak is observed at 950 cm⁻¹, indicating the presence of residual oscillators as a result of the various thermal decomposition reactions of FIG. 4. These residual oscillators are associated to the Si—ON oscillators of two (2) of the six (6) residual potential post-treatment compounds: SiONH and SiON₂. It is clear that the higher the temperature of the high temperature thermal treatment from 600 to 1100° C. in a nitrogen ambient, the more nitrogen incorporation and the more evident the Si—ON oscillators (i.e. some configurations of the residual potential: SiONH and/or SiON₂ post-treatment compounds).

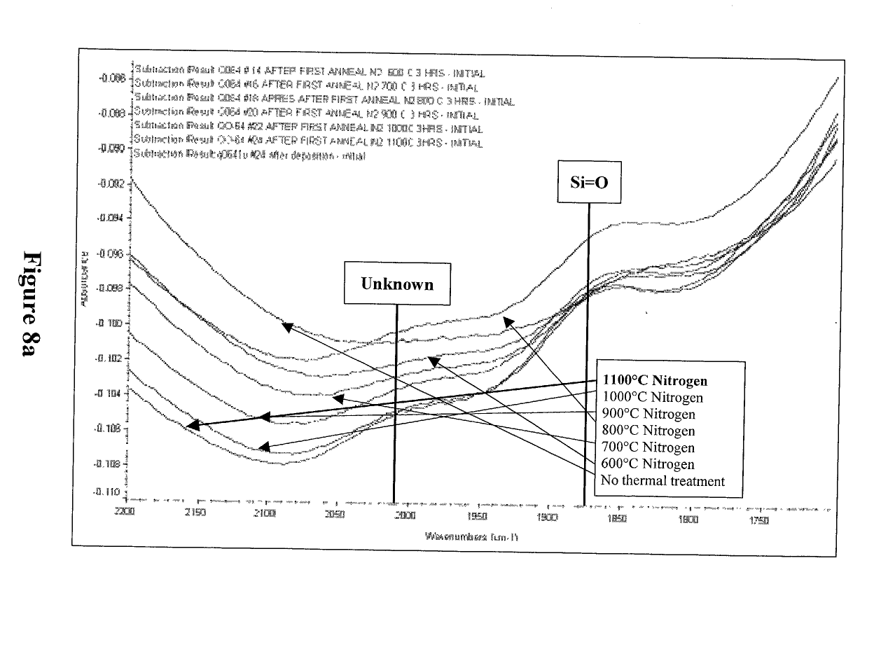

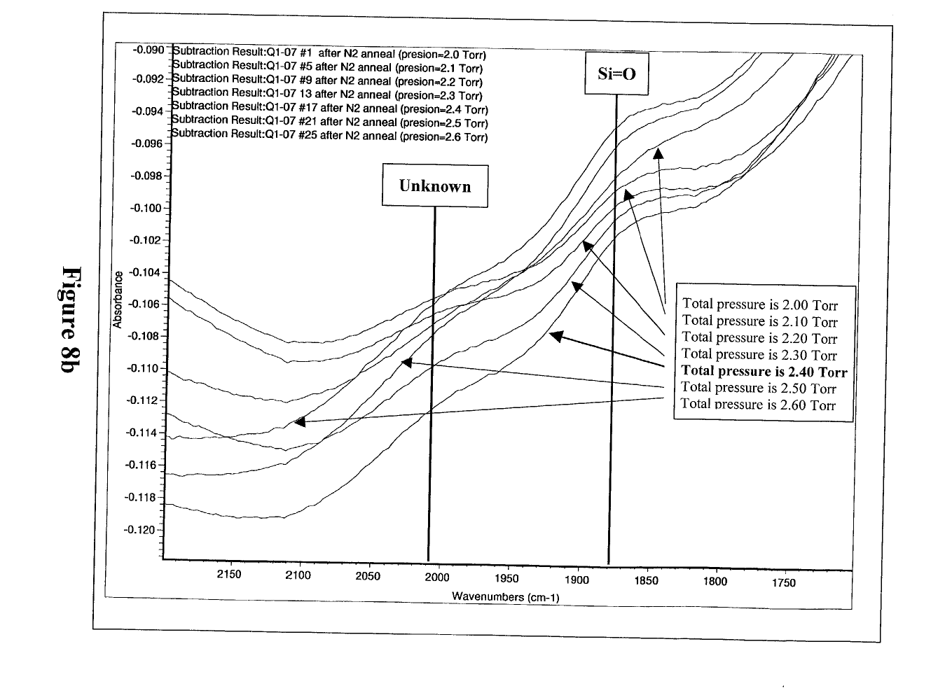

FIG. 8a shows the in-depth FTIR spectra from 1500 to 1600 cm⁻¹ of typically deposited PECVD silica films before and after a three hours long high temperature thermal treatment in a nitrogen ambient at a temperature of either 600, 700, 800,900, 1000 or 1100° C. This region of interest focuses on the N═N oscillators, centered at 1555 cm⁻¹, of the various post-treatment compounds described by the various chemical reactions of FIG. 4. It is apparent that the higher the thermal decomposition temperature of the high temperature thermal treatment in a nitrogen ambient, the better the elimination of N═N oscillators (which fifth harmonics could cause an optical absorption between 1.266 and 1.307 μm) with a complete elimination of residual N═N oscillators (i.e. some configurations of the residual potential SiON₂ post-treatment compounds) after a thermal treatment beyond 900° C. in a nitrogen ambient.

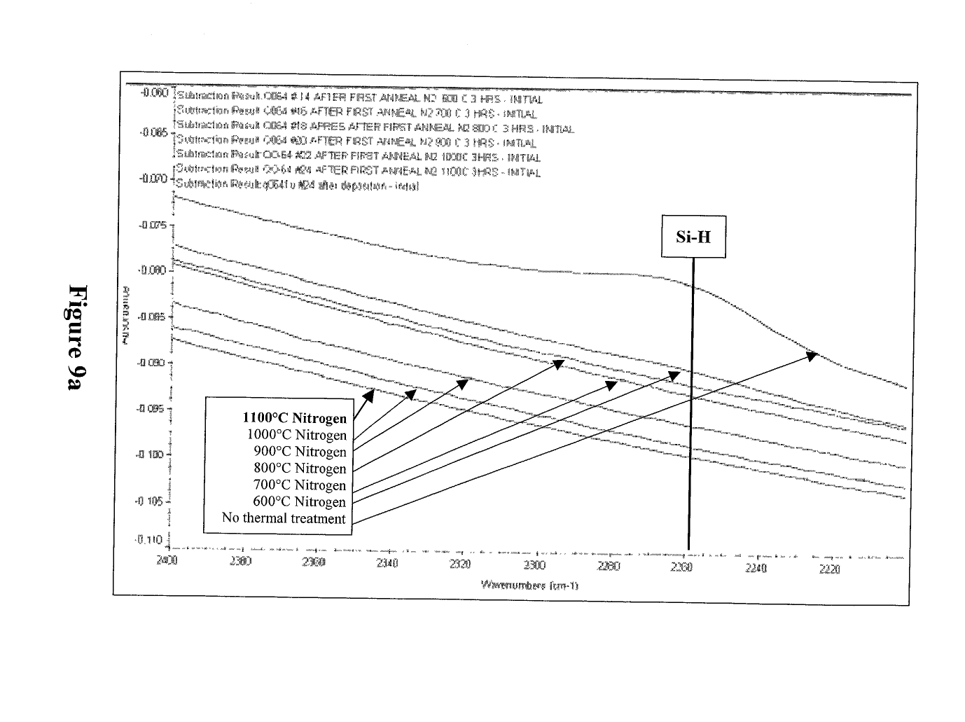

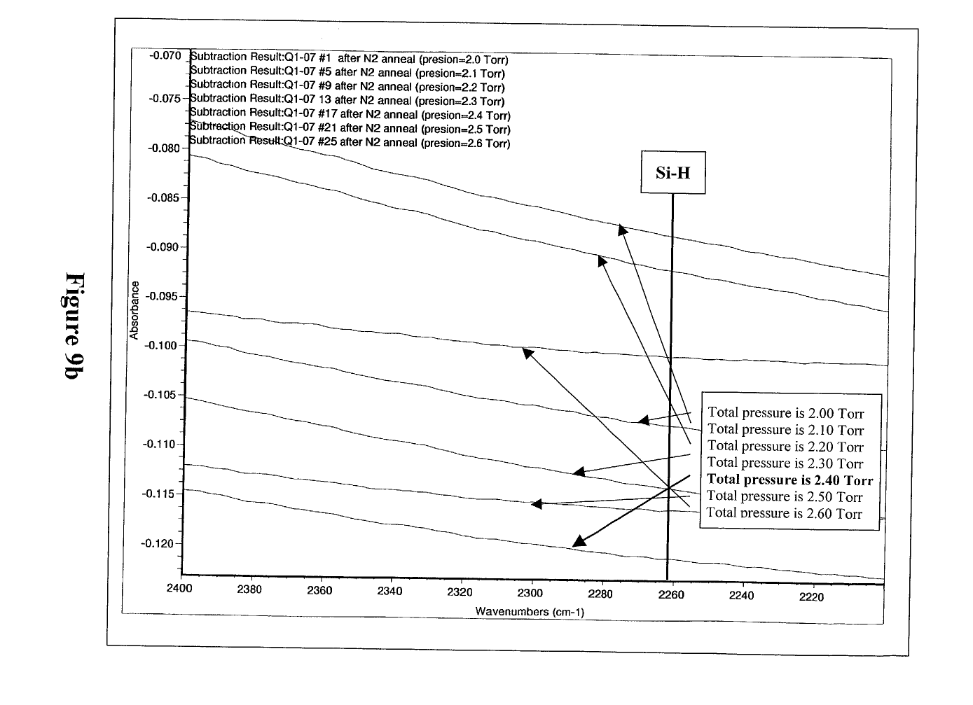

FIG. 9a shows the in-depth FTIR spectra from 1700 to 2200 cm⁻¹ of typically deposited PECVD silica films before and after a three hours long high temperature thermal treatment in a nitrogen ambient at a temperature of either 600, 700, 800, 900, 1000 or 1100° C. This region of interest focuses on the Si=O oscillators, centered at 1875 cm⁻¹ of four (4) of the six (6) residual potential post-treatment compounds: SiO₂, SiOH₂, SiONH and SiON₂. Another unknown absorption peak is also observed centered at 2010 cm⁻¹ but since this unknown oscillator does not have a higher harmonics which could cause optical absorption in the 1.30 to 1.55 μm optical bands, the search of its identity was not prioritized. It is clear that the higher the thermal decomposition temperature of the high temperature thermal treatment from 600 to 1100° C. in a nitrogen ambient, the more evident the Si═O oscillators (which fourth harmonics could cause an optical absorption between 1.282 and 1.389 μm) and the more evident the unknown oscillators which have no higher absorption harmonics between 1.300 and 1.550 μm.

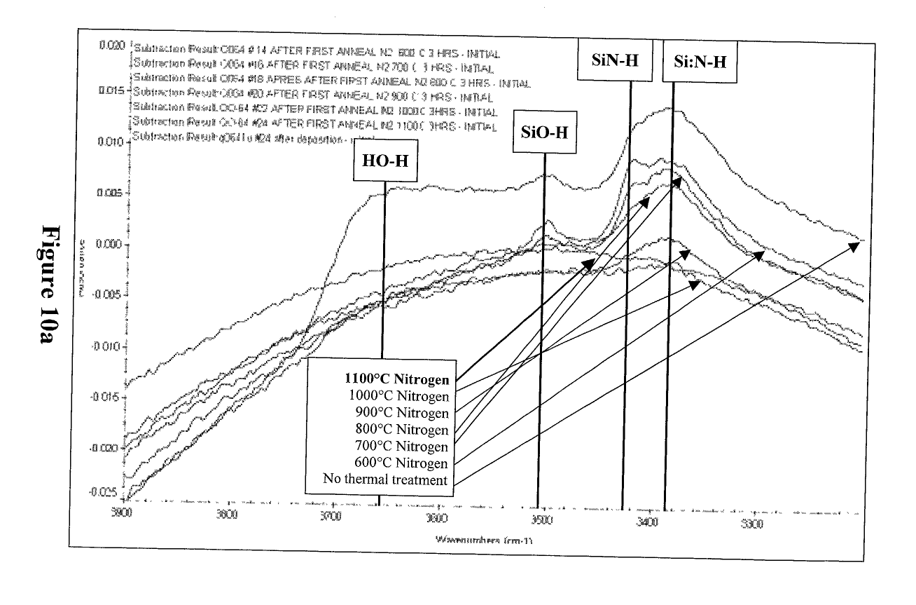

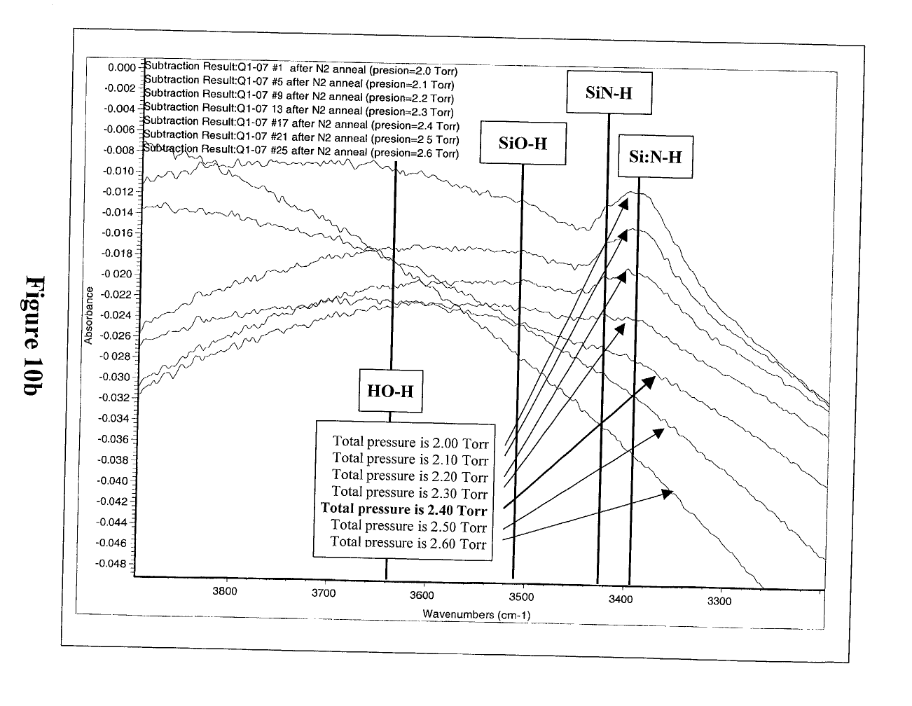

FIG. 10a shows the in-depth FTIR spectra from 2200 to 2400 cm⁻¹ of typically deposited PECVD silica films before and after a three hours long high temperature thermal treatment in a nitrogen ambient at a temperature of either 600, 700, 800, 900, 1000 or 1100° C. This region of interest focuses on the Si—H oscillators, centered at 2260 cm⁻¹ of three (3) of the six (6) residual potential post-treatment compounds: SiNH, SiOH₂, and SiONH. It is clear that the higher the thermal decomposition temperature of the high temperature thermal treatment in a nitrogen ambient, the better the elimination of Si—H oscillators (which third harmonics could cause an optical absorption between 1.443 and 1.508 μm) with a complete elimination of residual Si—H oscillators (i.e. some configurations of the residual potential SiNH, SiOH₂, and SiONH post-treatment compounds) after a thermal treatment beyond 600° C. in a nitrogen ambient.

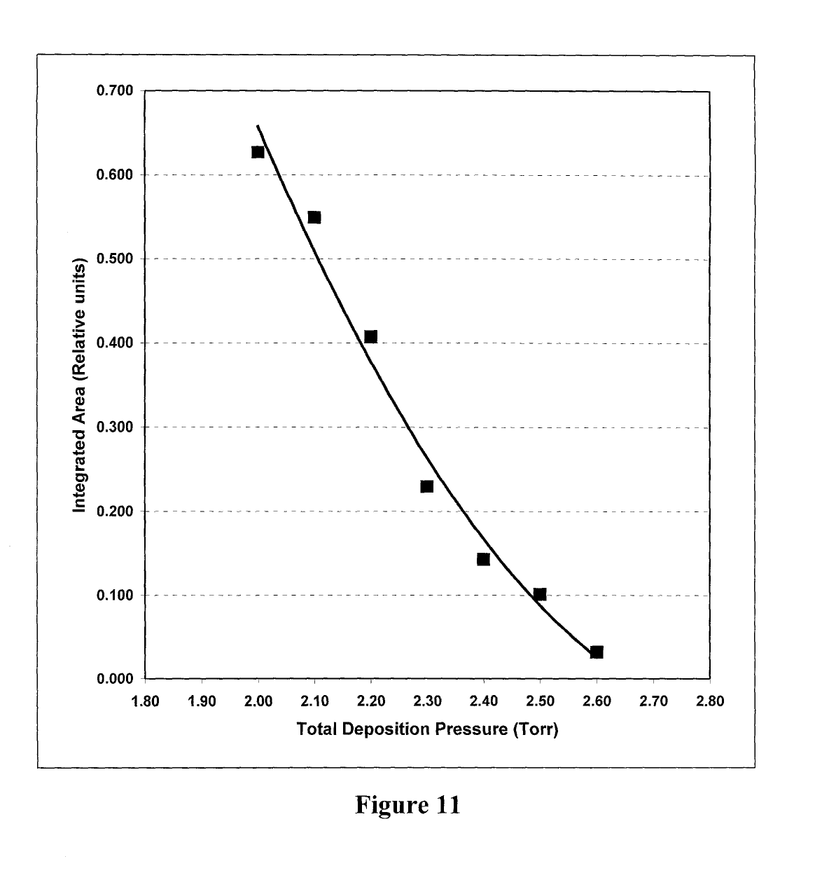

FIG. 11a shows the in-depth FTIR spectra from 3200 to 3900 cm⁻¹ of typically deposited PECVD silica films before and after a three hours long high temperature thermal treatment in a nitrogen ambient at a temperature of either 600, 700, 800, 900, 1000 or 1100° C. This region of interest focuses on the Si:N—H oscillators, centered at 3380 cm⁻¹, the SiN—H oscillators, centered at 3420 cm⁻¹, the SiO—H oscillators, centered at 3510 cm⁻¹ and the HO—H oscillators, centered at 3650 cm⁻¹ of three (3) of the six (6) residual potential post-treatment compounds: SiNH, SiOH₂ and SiONH. It is clear that the higher the thermal decomposition temperature of the high temperature thermal treatment from 600 to 1100° C. in a nitrogen ambient, the better the elimination of:

The HO—H oscillators (trapped water vapour in the micro-pores of the silica films and which second harmonics could cause an optical absorption between 1.333 and 1.408 μm) with a complete elimination over 600° C.;

The SiO—H oscillators (which second harmonics could cause an optical absorption between 1.408 and 1.441 μm) with a complete elimination over 900° C.;

The SiN—H oscillators (which second harmonics could cause an optical absorption between 1.445 and 1.479 μm) ) with a complete elimination over 1000° C.;

The Si:N—H oscillators (which second harmonics could cause an optical absorption between 1.445 and 1.515 μm) with are not yet completely eliminated at 1100° C. The complete elimination of the Si:N—H oscillators is extremely difficult because the nitrogen atom is bonded to the silicon atom of the SiO₂ network with two covalent bonds.

The upper FIG. 6a to FIG. 11a show that it is very difficult to completely eliminate the residual oscillators of the various undesirable Si—Oₓ—H_{Y}—N_{z} potential post-treatment compounds and achieve optical quality silica films from typically deposited PECVD silica films using thermal treatments at temperature between 600 and 1100° C. in a dry (nitrogen) ambient.

This improved Plasma Enhanced Chemical Vapour Deposition technique of silica films results in a better elimination of the undesirable residual Si:N—H oscillators (observed as a FTIR peak centered at 3380 cm⁻¹) after thermal treatments at lower post-deposition temperature as to provide improved optical quality silica waveguides with reduced optical absorption of in the 1.30 to 1.55 μm optical region in order to use them in the fabrication of high performance optical quality Multiplexers (Mux) and Demultiplexers (Dmux) with improved performances in the 1.30 bi-directional narrow optical band and/or in the 1.55 μm video signal optical band.

The improved Plasma Enhanced Chemical Vapour Deposition technique of silica films results in a better elimination of the undesirable residual Si:N—H oscillators (observed as a FTIR peak centered at 3380 cm⁻¹) after thermal treatments at lower post-deposition temperature and provide improved optical quality silica waveguides with reduced optical absorption of in the 1.30 to 1.55 μm optical region in order to use them in the fabrication of high performance optical quality Multiplexers (Mux) and Demultiplexers (Dmux) with improved performances in the 1.30 bi-directional narrow optical band and/or in the 1.55 μm video signal optical band.

FIG. 6b shows the basic FTIR spectra of silica films obtained with the improved PECVD deposition technique after a three hours long high temperature thermal treatment in a nitrogen ambient at a low temperature of 800° C. It is clear that the control of the deposition pressure of this improved PECVD deposition technique has a major effect on the FTIR spectra of the treated silica films (i.e. the better the four basic optical absorption peaks):

A gradually more intense and smaller FWHM Si—O—Si “rocking mode” absorption peak (between 410 and 510 cm⁻¹) as the deposition pressure is increased from 2.00 Torr up to an optimum 2.40 Torr and then a gradually less intense and larger FWHM Si—O—Si “rocking mode” absorption peak as the pressure is further increased from the optimum 2.40 Torr up to 2.60 Torr;

A slightly more intense and slightly smaller FWHM Si—O—Si “bending mode” absorption peak (between 740 and 880 cm⁻¹) can be obtained at an optimum deposition pressure of 2.40 Torr;

A gradually more intense and smaller FWHM Si—O—Si “in-phase-stretching mode” absorption peak (between 1000 and 1160 cm⁻¹) indicating a much more stoichiometric silica films with the optimum density and optimum Si—O—Si bond angle of 144°) as the deposition pressure is increased from 2.00 Torr up to an optimum 2.40 Torr and then a gradually less intense and FWHM Si—O—Si “in-phase-stretching mode” absorption peak as the pressure is further increased from the optimum 2.40 Torr up to 2.60 Torr;

A gradually more evident separation between the Si—O—Si “in-phase-stretching mode” absorption peak (1080 cm⁻¹) and the Si—O—Si “bending mode” absorption peak (810 cm⁻¹) with a gradually deeper valley between 850 and 1000 cm⁻¹ as the deposition pressure is increased from 2.00 Torr up to an optimum 2.40 Torr and then a gradually less evident separation and a gradually less deep valley between 850 and 1000 cm⁻¹ as the pressure is further increased from the optimum 2.40 Torr up to 2.60 Torr;

An in-depth examination of some infrared regions of the FTIR spectra of FIG. 6b with the help of the FTIR regions of the table of FIG. 5 could help verifying the gradual elimination of the various Si—Oₓ—H_{y}—N_{z} potential as-deposited compounds and verify the gradual achievement of pure SiO₂ with minimum optical absorption in the 1.30 to 1.55 μm optical bands as the pressure is changed around this optimum deposition pressure of 2.40 Torr.

FIG. 7b shows the in-depth FTIR spectra from 810 to 1000 cm⁻¹ of silica films obtained with the improved PECVD deposition technique after a three hours long high temperature thermal treatment in a nitrogen ambient at a low temperature of 800° C. This region of the FTIR spectra should show a net separation between the Si—O—Si “in-phase-stretching mode” absorption peak (1080 cm⁻¹) and the Si—O—Si “bending mode” absorption peak (810 cm⁻¹) and should show a deep valley between 850 and 1000 cm⁻¹. It is clearly observed that there is a gradual elimination of the residual Si—OH oscillators (centered at 885 cm⁻¹) of the residual SiOH₂ residual post-treatment compound (FIG. 4) as the deposition pressure is increased from 2.00 Torr up to the optimum pressure of 2.40 Torr and that the elimination gradually get worse as the pressure is further increased from the optimum 2.40 Torr up to 2.60 Torr. Similarly, it is clearly observed that there is a gradual elimination of the Si—ON oscillators (centered at 950 cm⁻¹) of the residual SiONH and/or SiON₂ post-treatment compounds (FIG. 4) as the deposition pressure is increased from 2.00 Torr up to the optimum 2.40 Torr and then gradually less effective as the deposition pressure is further increased from this optimum 2.40 Torr up to 2.60 Torr. The optimum separation and deep valley observed at 2.40 Torr is an indication that the silica films resulting from this optimum deposition pressure are composed of high quality SiO₂ material.

FIG. 8b shows the in-depth FTIR spectra from 1500 to 1600 cm⁻¹ of silica films obtained with the improved PECVD deposition technique after a three hours long high temperature thermal treatment in a nitrogen ambient at a low temperature of 800° C. This region focuses on the N═N oscillators (centered at 1555 cm⁻¹ and which fifth harmonics could cause an optical absorption between 1.266 and 1.307 μm) of the various residual post-treatment compounds of FIG. 4. It is observed that these oscillators are gradually eliminated as the deposition pressure is increased from 2.00 up to the optimum pressure of 2.40 Torr and that the elimination is gradually (slight effect) less complete as the pressure is further increased from this optimum pressure of 2.40 up to 2.60 Torr.

FIG. 9b shows the in-depth FTIR spectra from 1700 to 2200 cm⁻¹ of silica films obtained with the improved PECVD deposition technique after a three hours long high temperature thermal treatment in a nitrogen ambient at a low temperature of 800° C. This region focuses on the Si═O oscillators (centered at 1875 cm⁻¹) and on the unknown oscillator (centered at 2010 cm⁻¹) of the various residual post-treatment compounds described by FIG. 4. It seems that even at the optimum deposition pressure of 2.40 Torr, it is not possible to eliminate the Si═O oscillators (which fourth harmonics could cause an optical absorption between 1.282 and 1.389 μm) and the unknown oscillators (which does not have a higher harmonics which could cause optical absorption in the 1.30 to 1.55 μm optical bands) at any of the deposition pressures. This limitation is not that important since only the fourth harmonics of the Si═O oscillators which can absorb in the 1.30 to 1.55 μm optical bands.

FIG. 10b shows the in-depth FTIR spectra from 2200 to 2400 cm⁻¹ of silica films obtained with the improved PECVD deposition technique after a three hours long high temperature thermal treatment in a nitrogen ambient at a low temperature of 800° C. This region focuses on the Si—H oscillators (centered at 2260 cm⁻¹) of the various residual post-treatment compounds of FIG. 4. It is clear that the Si—H oscillators (which third harmonics could cause an optical absorption between 1.443 and 1.508 μm) are completely eliminated for all deposition pressures.

FIG. 11b shows the in-depth FTIR spectra from 3200 to 3900 cm⁻¹ of silica films obtained with the improved PECVD deposition technique after a three hours long high temperature thermal treatment in a nitrogen ambient at a low temperature of 800° C. This region focuses on the Si:N—H oscillators (centered at 3380 cm⁻¹), on the SiN—H oscillators (centered at 3420 cm⁻¹), on the SiO—H oscillators (centered at 3510 cm⁻¹) and on the HO—H oscillators (centered at 3650 cm⁻¹) of the various residual post-treatment compounds described by FIG. 4. It is clear that all these oscillators are gradually eliminated as the deposition pressure is increased from 2.00 to 2.60 Torr.

The HO—H oscillators (trapped water vapour in the micro-pores of the silica films and which second harmonics could cause an optical absorption between 1.333 and 1.408 μm) are completely eliminated for all deposition pressures;

The SiO—H oscillators (which second harmonics could cause an optical absorption between 1.408 and 1.441 μm) are completely eliminated for all deposition pressures;

The SiN—H oscillators (which second harmonics could cause an optical absorption between 1.445 and 1.479 μm) are gradually eliminated as the deposition pressure is increased from 2.00 Torr to 2.60 Torr;

The Si:N—H oscillators (which second harmonics could cause an optical absorption between 1.445 and 1.515 μm are gradually eliminated as the deposition pressure is increased from 2.00 Torr to 2.60 Torr. This complete elimination at such a low thermal treatment temperature of only 800° C. is really spectacular because it requires thermally breaking two covalent bonds binding the nitrogen atom to the silicon atom of the SiO₂ network. It is to be concluded that the increase of deposition pressure from 2.00 Torr to 2.60 Torr minimizes the formation of such residual Si:N—H oscillators with two covalent bonds. By looking at FIG. 2 and FIG. 4 it appears that this gradual increase of deposition pressure from 2.00 to 2.60 Torr may gradually prevent the formation of as deposited residual SiONH, SiONH₃, SiON₃H and SiON₃H₃ compounds which would result in the residual SiONH post-treatment compound responsible of the residual Si:N—H oscillators after thermal treatment.

A systematic comparison between: (FIGS. 5a and 5b), (FIGS. 6a and 6b), (FIGS. 7a and 7b), (FIGS. 8a and 8b), (FIGS. 9a and 9b) as well as (FIGS. 10a and 10b) shows the spectacular benefits of the improved PECVD deposition technique which results in a substantially total elimination of the various undesirable Si—Oₓ—H_{y}—N_{z} potential post-treatment compounds after a low temperature (800° C.) thermal treatment in a nitrogen ambient and in particular of the residual SiONH post-treatment compounds which can still be detected by the residual Si:N—H oscillators (centered at 3380 cm⁻¹ and which second harmonics causes an optical absorption between 1.445 and 1.515 μm) of FIG. 11a's 1100° C. curve. By contrast, it is clear that these residual Si:N—H oscillators are completely eliminated from FIG. 11b's 2.40 Torr curve, even after a much lower temperature (800° C.) thermal treatment in the same nitrogen ambient.

The improved Plasma Enhanced Chemical Vapour Deposition technique of silica films results in a better elimination of the undesirable residual Si:N—H oscillators (observed as a FTIR peak centered at 3380 cm⁻¹) after thermal treatment at lower post-deposition temperature so as to provide improved optical quality silica waveguides with reduced optical absorption of in the 1.30 to 1.55 μm optical region in order to use them in the fabrication of high performance optical quality Multiplexers (Mux) and Demultiplexers (Dmux) with improved performances in the 1.30 bi-directional narrow optical band and/or in the 1.55 μm video signal optical band.

The comparison of the various PECVD approaches summarised in FIG. 1 shows that the novel PECVD approach has a number of advantages: it does not require the use of B and/or P; it does not use TEOS; it does not use O₂; it does not use CF₄; it does not use SiH₄, N₂O and NH₃ gas mixtures; it does not use SiH₄, N₂O and Ar gas mixtures; it does use more then just SiH₄ and N₂O gas mixtures; and while it does use SiH₄, N₂O and N₂ gas mixtures, it does so in a very different way from the cited prior art (Imoto K., 1993) which only reports the control of the mass flow rates of the three gases as a way to control the transparency and refractive index of the silica film.

The described technique uses an independent control of the SiH₄, N₂O and N₂ gases as well as of the total deposition pressure via an automatic control of the pumping speed of the vacuum pump. As mentioned before the fundamental principles of classical thermodynamics predict that the equilibrium constants of the various chemical reactions of FIG. 3 will be affected by the total deposition pressure and will result in an improved elimination of some of thirty-five (35) Si—Oₓ—H_{y}—N_{z} potential as-deposited compounds due to an improved elimination of N₂, O₂, HNO, NH₃, H₂O, and H₂ gaseous compounds that must be eliminated from the micro-pores of the growing silica films up to their surface and from their surface through the gaseous boundary layer present near their surface. This effect is due to the fact that many of the chemical reactions of FIG. 3 are associated with a modification of the number of gaseous compounds; i.e. the number of gaseous product compound molecules is different then three, the number of gaseous reactant compound molecules:

SiH₄(g)+2N₂O(g)→The various products of FIG. 3

In other words, unlike the various cited references which use: SiH₄/N₂O gas flow ratios in a two-dimensional space (a unique independent variable, the SiH₄/N₂O ratio, and the observed variable, the observed film characteristics); or SiH₄/N₂O/N₂ gas flow ratios in a three-dimensional space (a first independent variable, the SiH₄/N₂O ratio, a second independent variable, N₂O/N₂ ratio, and the observed variable, the observed film characteristics); SiH₄, N₂O, N₂ gas flows in a four-dimensional space (a first independent variable, the SiH₄ flow, a second independent variable, the N₂O flow, a third independent variable the N₂ flow, and the observed variable, the observed film characteristics); the technique described in this patent application uses a five-dimensional space (a first independent variable, the SiH₄ flow, a second independent variable, the N₂O flow, a third independent variable the N₂ flow, a fourth independent variable, the total deposition pressure (controlled by an automatic adjustment of the pumping speed), and the observed variable, the observed film characteristics) to optimize the silica films characteristics.

The spectacular effect of the total deposition pressure was demonstrated by the FTIR spectra of: FIG. 5b, FIG. 6b, FIG. 7b, FIG. 8b, FIG. 9b and FIG. 10b which compare the results of silica films deposited at the following fixed gas flows:

The first independent variable, the SiH₄ gas flow, was fixed at 0.20 std liter/min;

The second independent variable, the N₂O gas flow, was fixed at 6.00 std liter/min;

The third independent variable, the N₂ gas flow, was fixed at 3.15 std liter/min.

Only the fourth independent variable, the total deposition pressure, was varied:

Total deposition pressure of 2.00 Torr;

Total deposition pressure of 2.10 Torr;

Total deposition pressure of 2.20 Torr;

Total deposition pressure of 2.30 Torr;

Total deposition pressure of 2.40 Torr;

Total deposition pressure of 2.50 Torr;

Total deposition pressure of 2.60 Torr;

The spectacular effect of this fourth independent variable, the total deposition pressure, on the elimination of the various undesirable Si—Oₓ—H_{y}—N_{z} potential post-treatment compounds after a low temperature (800° C.) thermal treatment in a nitrogen ambient is clearly demonstrated by comparing: (FIGS. 5a and 5b), (FIGS. 6a and 6b), (FIGS. 7a and 7b), (FIGS. 8a and 8b), (FIGS. 9a and 9b) as well as (FIGS. 10a and 10b). In particular, it is demonstrated that the residual Si:N—H oscillators of the residual SiONH post-treatment compounds (centered at 3380 cm⁻¹ and which second harmonics causes an optical absorption between 1.445 and 1.515 μm) are completely eliminated from FIG. 11b's 2.60 Torr curve even after a low temperature thermal treatment of only 800° C. in nitrogen. This contrasts with the results of FIG. 11a which shows that a much higher temperature thermal treatment of 1100° C. in nitrogen is required to eliminate the same oscillators from silica films obtained from typical non-optimized PECVD conditions.

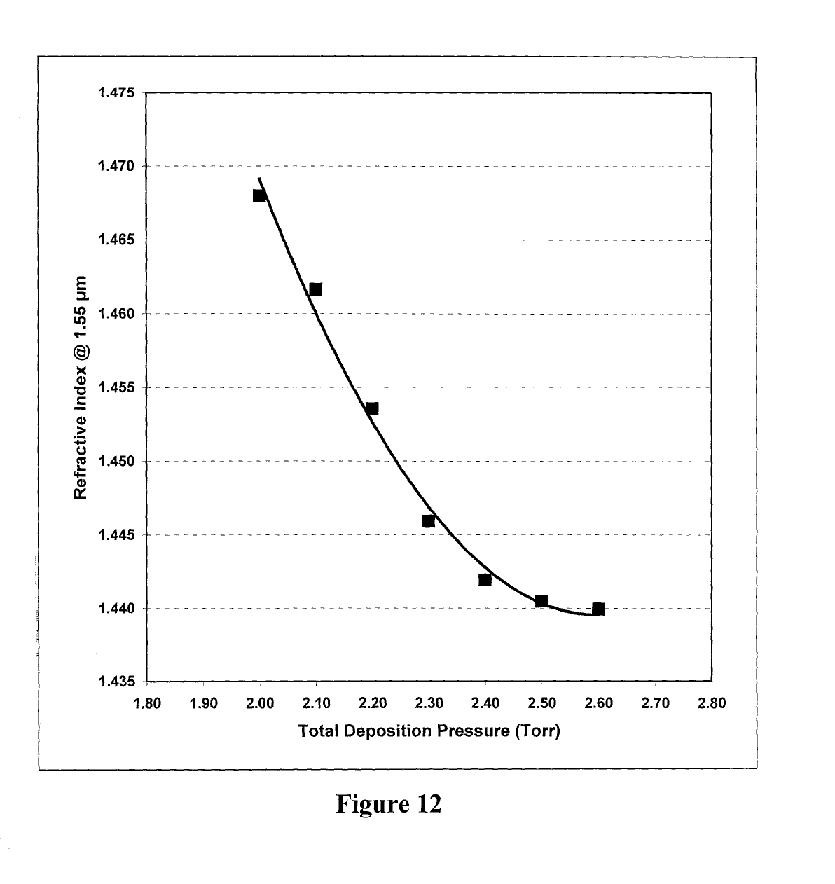

FIG. 12 summarises the spectacular effect of this fourth independent variable, the total deposition pressure, on the integrated area under the 3380 cm⁻¹ FTIR peak of the Si:N—H oscillators of PECVD silica films deposited at a fixed SiH₄ gas flow of 0.20 std liter/min, at a fixed N₂O gas flow of 6.00 std liter/min and at a fixed N₂ gas flow of 3.15 std liter/min and following a thermal treatment in a nitrogen ambient at 800° C.

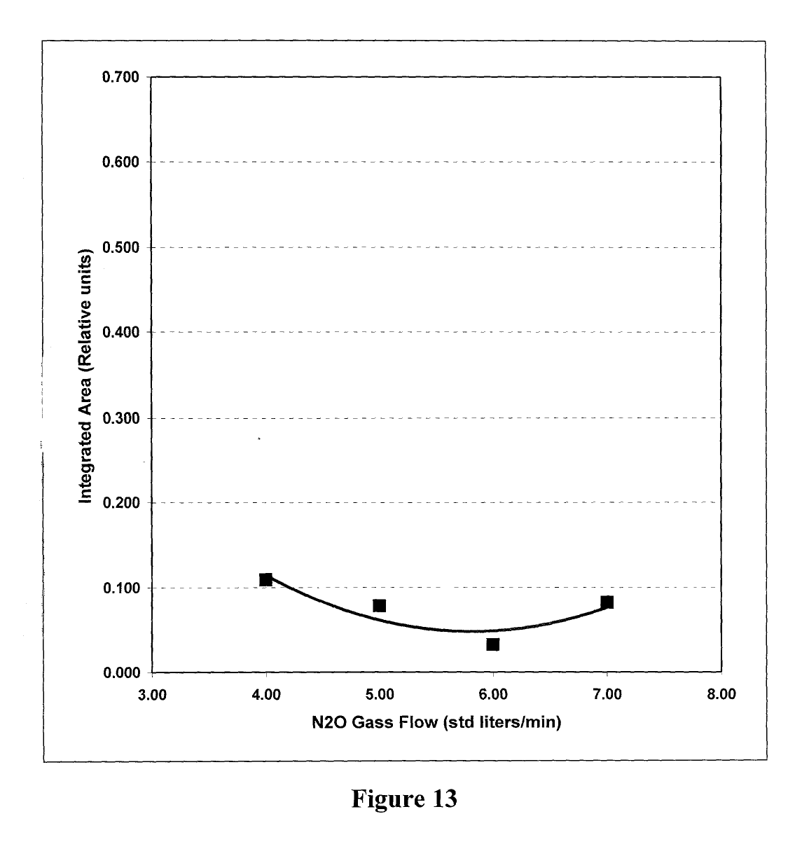

The elimination of the residual Si:N—H oscillators at lower temperature is not the only benefit of the novel technique according to the invention. FIG. 13 shows the effect of the total deposition pressure on the 1.55 μm refractive index of PECVD silica films deposited at a fixed SiH₄ gas flow of 0.20 std liter/min, at a fixed N₂O gas flow of 6.00 std liter/min and at a fixed N₂ gas flow of 3.15 std liter/min and following a thermal treatment in a nitrogen ambient at 800° C. It is again clear that the introduction of the fourth independent variable, the total deposition pressure, is critical for the development of optimized optical silica films. The refractive index at the operation wavelength of 1.55 μm is certainly one of the most important film characteristic. This FIG. 13 clearly indicates that the control of this parameter is of prime importance for the repeatable achievement of high quality optical silica films. At this point it should be noted that typical vacuum pumping systems used in PECVD equipment (i.e. rotary vane mechanical pumps, roots blowers, turbo-molecular pumps or others) suffer from many sources of pumping speed variation over time (variation of the AC electrical power source, variation of the pumping conductance due to accumulation of residues in the protection scrubber or pumping lines etc) and it is then expected that a PECVD deposition condition involving a fixed set of gas flow parameters will suffer from a non-repeatability of the observed film characteristics.

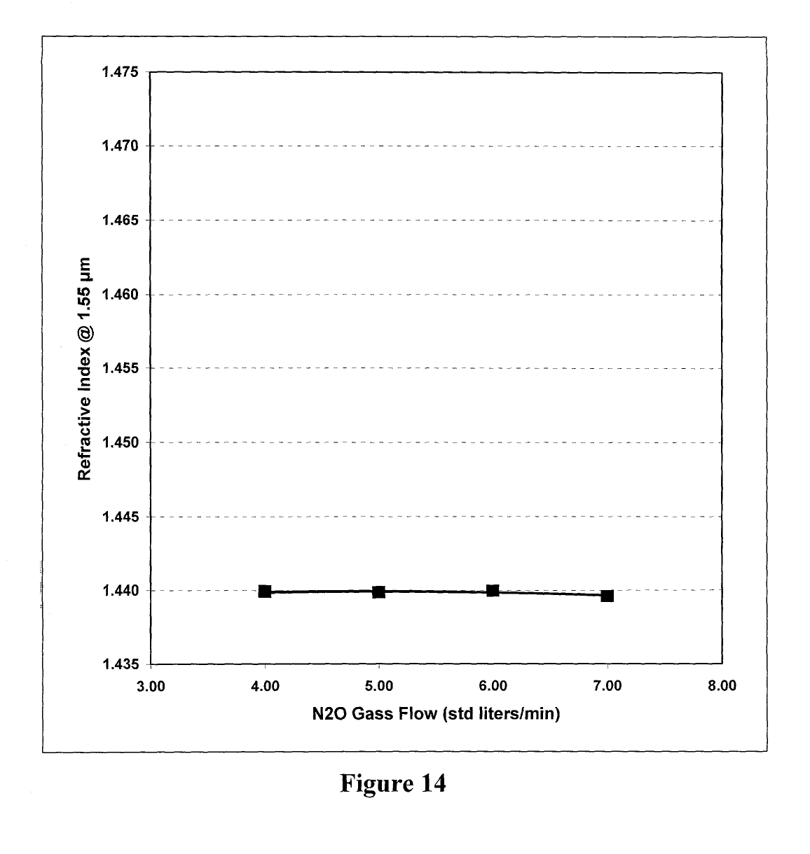

FIG. 14 summarises the effect of the N₂O mass flow rate on the integrated area under the 3380 cm⁻¹ FTIR peak of the Si:N—H oscillators of PECVD silica films deposited at a fixed SiH₄ gas flow of 0.20 std liter/min, at a fixed N₂ gas flow of 3.15 std liter/min, at a fixed total deposition pressure of 2.60 Torr and following a thermal treatment in a nitrogen ambient at 800° C. It is very clear that once the local optimum operation point is found in the five dimensional space (four independent variables and one output measurement), there might be no further relationship between the residual optical absorption of the obtained silica films and that the SiH₄-to-N₂O gas flow ratio is actually not a determining factor. Again, since the optical transparency at the operation wavelength of 1.55 μm is certainly one of the most important film characteristic of optical silica waveguides, this FIG. 14 clearly indicates that, unlike for what is reported in the previous art literature, the SiH₄-to-N₂O gas flow ratio is not an important factor in the definition of the optical properties of silica films.

FIG. 15 shows the effect of the N₂O gas flow on the 1.55 μm refractive index of PECVD silica films deposited at a fixed SiH₄ gas flow of 0.20 std liter/min, at a fixed N₂ gas flow of 3.15 std liter/min, at a fixed total deposition pressure of 2.60 Torr and following a thermal treatment in a nitrogen ambient at 800° C. It is again very clear that once the local optimum operation point is found in the five dimensions space (four independent variables and one output measurement), there might be no more relationship between the measured film characteristics and the ratio of SiH₄-to-N₂O gas flow ratio. Again, since the refractive index at the operation wavelength of 1.55 μm is certainly one of the most important film characteristic of optical silica waveguides, this FIG. 15 clearly indicates that the SiH₄-to-N₂O gas flow ratio is not a critical factor in the definition of the optical properties of silica films.

It will be appreciated by persons skilled in the art that a number of variants of the invention as described are possible. Purely, by way of non-liming example, the PECVD silica films could be deposited with some molecules incorporating Phosphorus, Boron, Germanium, Titanium or Fluorine to modify the refractive index of the optimized films. The PECVD silica films could be deposited at a temperature different from 400° C. It could be deposited at any temperature between 100 and 650° C.

The PECVD equipment could be different from the Novellus Concept One. The requirement is to provide independent control of the four basic control parameters: SiH₄ gas flow rate, N₂O gas flow rate, N₂ gas flow rate and total deposition pressure.

The found local optimum (SiH₄ gas flow of 0.20 std liter/min, N₂O gas flow of 6.00 std liter/min, N₂ gas flow of 3.15 std liter/min and a total deposition pressure of 2.60 Torr) is this four-independent-variables space. A different set of coordinates (SiH₄, N₂O, N₂, deposition pressure) could be found using the same Novellus Concept One equipment.

A different set of coordinates (SiH₄, N₂O, N₂, deposition pressure) could be found for another type of PECVD equipment.

The SiH₄ silicon raw material gas could be replaced by an alternate silicon containing gas, such as: silicon tetra-chloride, SiCl₄, silicon tetra-fluoride, SiF₄, disilane, Si₂H₆, dichloro-silane, SiH₂Cl₂, difluoro-silane, SiH₂F₂ or any other silicon containing gases involving the use of hydrogen, H, chlorine, Cl, fluorine, F, bromine, Br, and iodine, I.

The N₂O oxidation gas could be replaced by an alternate oxygen containing gas, such as: oxygen, O₂, nitric oxide, NO₂, water, H₂O, hydrogen peroxide, H₂O₂, carbon monoxide, CO or carbon dioxide, CO₂.

The N₂ carrier gas could be replaced by an alternate carrier gas, such as: helium, He, neon, Ne, argon, Ar or krypton, Kr.

A different set of coordinates (silicon source, oxygen source, carrier gas, deposition pressure) could be found for other alternate chemistries.

The high temperature thermal treatment in nitrogen could be performed at a temperature different than 800° C. The preferred range is from 400 to 1200° C.

The described invention thus results in a Plasma Enhanced Chemical Vapour Deposition technique of silica films that results in a better elimination of the undesirable residual Si:N—H oscillators (observed as a FTIR peak centered at 3380 cm⁻¹) after thermal treatments at lower post-deposition temperature to provide improved optical quality silica waveguides with reduced optical absorption of in the 1.30 to 1.55 μm optical region in order to use them in the fabrication of high performance optical quality Multiplexers (Mux) and Demultiplexers (Dmux) with improved performances in the 1.30 bi-directional narrow optical band and/or in the 1.55 μm video signal optical band.

The optical region of interest is not limited to the 1.30 to 1.55 μm optical region since the higher oscillation harmonics of the eliminated oscillators have other optical benefits at longer or shorter wavelengths. The wavelengths of the first, second, third and fourth harmonics of these oscillators are also included in the invention.

The invention has application in any manufacturing processes involving the use of high quality silica films, such as: Photonics devices other than Mux/Dmux devices; Semiconductor devices; Micro Electro Mechanical Systems (MEMS); Bio-chips; Lab-on-a-chip devices; and Multi-chip modules.

We claim:

1. A method of depositing an optical quality silica film on a substrate, comprising:
forming said optical quality silica film on said substrate by plasma enhanced chemical vapor deposition (PECVD) in the presence of gases while controlling the total pressure of said gases; and
subjecting the as-deposited film to a low temperature treatment between 400° to 1200° C. to minimize the presence of contaminant compounds in said film.

2. A method as claimed in claim 1, wherein said total pressure is controlled to minimize the presence of Si—Oₓ—H_{y}—Nz compounds after said low temperature treatment.

3. A method as claimed in claim 2, wherein said low temperature treatment is about 800° C.

4. A method as claimed in claim 1, wherein the total gas pressure is controlled to be in the range of 2.0 to 2.6 Torr.

5. A method as claimed in claim 4, wherein said total gas pressure is about 2.4 Torr.

6. A method as claimed in claim 4, wherein said film is deposited in a vacuum chamber whose pressure is maintained by a vacuum pump having a controllable pumping speed, and said total gas pressure is maintained by controlling said pumping speed.

7. A method as claimed in claim 4, wherein said film is deposited at a temperature between 100 and 650° C.

8. A method as claimed in claim 7, wherein said film is deposited at a temperature of about 400° C.

9. A method as claimed in claim 4, wherein said gases comprise a raw material gas, an oxidation gas, and a carrier gas.

10. A method as claimed in claim 9, wherein said reactive gas is selected from the group consisting of: silicon tetra-chloride, SiCl₄, silicon tetra-fluoride, SiF₄, disilane, Si₂H₆, dichloro-silane, SiH₂Cl₂, difluoro-silane, SiH₂F₂ and any other silicon containing gases involving the use of hydrogen, H, chlorine, Cl, fluorine, F, bromine, Br, and iodine, I.

11. A method as claimed in claim 10, wherein said oxidation gas is selected from the group consisting of: oxygen, O₂, nitric oxide, NO₂, water, H₂O, hydrogen peroxide, H₂O₂, carbon monoxide, CO or carbon dioxide, CO₂.

12. A method as claimed in claim 11, wherein said carrier gas is selected from the group consisting of: helium, He, neon, Ne, argon, Ar or krypton, Kr.

13. A method as claimed in claim 9 wherein said raw material gas is SiH₄, said oxidation gas is N₂O, and said carrier gas is N₂ carrier gas.

14. A method as claimed in claim 9, wherein the flow rates of said gases are also controlled to optimize the quality of the deposited films after said low temperature treatment.

15. A method as claimed in claim 13, wherein the flow rates of said gases are also controlled to optimize the quality of the deposited films after said low temperature treatment.

16. A method as claimed in claim 15, wherein the flow rate of the SiH₄ is about 0.2 std liter/min.

17. A method as claimed in claim 16, wherein the flow rate of the N₂O is about 6.00 std liter/min.

18. A method as claimed in claim 17, wherein the flow rate of the N₂ is about 3.15 std liter/min.

19. A method as claimed in claim 1, wherein modifiers are incorporated into said films during deposition to modify the resulting refractive index.

20. A method as claimed in claim 19, wherein said modifiers are selected from the group consisting of: Phosphorus, Boron, Germanium, Titanium or Fluorine.

21. A method of depositing an optical quality silica film on a substrate, comprising:
forming said optical quality silica film on said substrate at a temperature between 100 and 650° C. by plasma enhanced chemical vapor deposition (PECVD) in the presence of a raw material gas, an oxidation gas, and a carrier gas while controlling the total pressure of said gases to a pressure of between 2.0 to 2.6 Torr; and
subjecting the as-deposited film to a low temperature treatment at about 800° C. to minimize the presence of Si—Oₓ—H_{y}—Nz compounds after said low temperature treatment.

22. A method as claimed in claim 21, wherein said film is deposited in a vacuum chamber whose pressure is maintained by a vacuum pump having a controllable pumping speed, and said total gas pressure is maintained by controlling said pumping speed.

23. A method as claimed in claim 21, wherein said film is deposited at a temperature of about 400° C.

24. A method as claimed in claim 21, wherein said raw material gas is SiH₄, said oxidation gas is N₂O, and said carrier gas is N₂ carrier gas.

25. A method as claimed in claim 24, wherein the flow rate of the SiH₄ is controlled to be about 0.2 std liter/min, the flow rate of the N₂O is controlled to be about 6.00 std liter/min., and the flow rate of N₂ is controlled to be about 3.15 std liter/min.
